(19) United States
(12) Patent Application Publication
(10) Pub. No.: US 2012/0211351 A1
(43) Pub. Date: Aug. 23, 2012

(54) METHOD AND APPARATUS FOR FORMING SILICON DOTS AND METHOD AND APPARATUS FOR FORMING A SUBSTRATE WITH SILICON DOTS AND INSULATING FILM

(76) Inventors: Atsushi Tomyo, Sakai-shi (JP); Hirokazu Kaki, Kyoto-shi (JP); Eiji Takahashi, Kyoto-shi (JP)

(21) Appl. No.: 12/513,361

(22) PCT Filed: Oct. 29, 2007
(86) PCT No.: PCT/JP2007/070992

§ 371 Date: Feb. 3, 2010

(30) Foreign Application Priority Data
Nov. 8, 2006 (JP) 2006-303153

(51) Int. Cl. C23C 14/34

(52) U.S. Cl. 204/192.1; 204/298.08

(57) ABSTRACT

Silicon dots are formed at a relatively low temperature, while suppressing occurrence of defects and clustering of silicon dots and damages caused by plasma, with high controllability of particle diameter and high reproducibility between substrates. Moreover, silicon dots and insulating film are formed at a relatively low temperature, with high controllability of the particle diameter of the silicon dots, high controllability of the thickness of the insulating film and high reproducibility between substrates. A method and an apparatus 1 for forming silicon dots (method and apparatus A for forming a substrate with silicon dots and insulating film) in which inductively coupled plasma is produced by an internal antenna 12 (22) with low inductance from a gas for forming silicon dots (a gas for forming insulating film); silicon dots SiD (insulating film F) are formed on a substrate S in the inductively coupled plasma; the substrate S is placed in a state that it is not exposed to unstable plasma when the plasma is in an unstable state; and the substrate S is exposed to stabilized plasma when the plasma is stabilized to start formation of the silicon dots (formation of insulating film).

### TECHNICAL FIELD

The present invention relates to a method and an apparatus for forming silicon dots (i.e., so-called silicon nanoparticles) of minute sizes that can be used as electronic device materials, light emission materials and others. The present invention also relates to a method and an apparatus for forming a substrate with silicon dots and an insulating film which can be used for semiconductor devices such as MOS capacitors and MOS-FETs, in which the insulating film is formed over the silicon dots.

### BACKGROUND ART

As a method for forming silicon dots, such physical manners have been known that silicon is heated and vaporized in an inert gas by excimer laser or the like, and also the in-gas vaporizing method is known (see Kanagawa-ken Sangyo Gijutu Sougou Kenkyusho Research Report No. 9/2003, pp 77-78). The latter method is configured to heat and vaporize the silicon by high-frequency induction heating or arc discharge instead of laser.

JP2004-179658A discloses a method of forming silicon dots, wherein material gases, i.e., silane and dichlorosilane, are supplied into a CVD chamber, and silicon dots are formed on a heated substrate. In this method, silicon dots are grown from nucleuses through the step of forming nucleuses for growing silicon dots on the substrate.

However, the method of heating and vaporizing the silicon by laser irradiation cannot uniformly control an energy density for irradiating the silicon with the laser, and therefore it is difficult to uniformize the particle diameters and density distribution of silicon dots.

In the in-gas vaporizing method, the silicon is heated nonuniformly, and therefore the particle diameters and the density distribution of silicon dots cannot be uniformized without difficulty.

In the formation of silicon dots by the foregoing CVD method, the substrate must be heated to 550° C. or higher for forming the nucleuses which serve as the basis of the silicon dot growth on the substrate, and the substrate of a low heat-resistant temperature cannot be employed, which narrows a selection range of the substrate materials. Furthermore, forming the silicon dots at a high temperature has some adverse influences: For example, Si—H bonds on the surfaces of the silicon dots are cut to produce defects, and silicon dots are clustered.

For these reasons, methods and apparatuses for forming silicon dots by the plasma CVD method which enables forming silicon dots at a relatively low temperature have been studied.

An example of known methods for forming an insulating film is the technique of causing an insulating film formation target substrate to undergo heat oxidation to form an insulating heat-oxidized film (for example, the technique of causing a silicon substrate to undergo heat oxidation at a high temperature of about 800° C. to 900° C. to form an insulating silicon oxide film) (refer to JP2004-179658A mentioned above, for example). In this method, a substrate having a low heat-resistant temperature cannot be employed, which narrows a selection range of the substrate materials.

However, there is also a known method of forming an insulating film by the plasma CVD method in which the plasma of a gas for forming an insulating film is produced, and an insulating film is formed on the substrate in the plasma at a relatively low temperature.

Now referring to the plasma CVD method, the method in which capacitively coupled plasma is produced by using parallel plate electrodes has been long known. This method, however, is unsuitable for plasma processes such as forming a film on a substrate having a large area since there is a limit in increasing the size of the electrodes. Today, much attention is focused on such an apparatus that an antenna is placed outside or inside a plasma producing chamber, and high-frequency power is applied to the antenna so that inductively coupled plasma is produced from the gas in the plasma producing chamber.

In particular, from the perspective of the possibility of improvement in the efficiency of utilization of the input power and other advantages, inductively coupled plasma CVD apparatuses of internal antenna type in which the antenna is disposed in the plasma producing chamber are drawing attention. A plasma CVD apparatus of this type is described in, for example, JP2001-35697A.

JP2001-35697A has the following description: when the internal antenna is used, the raised potential of plasma, due to the electrostatic coupling of an antenna conductor becomes significant as the density of plasma is increased due to an increase in the input high-frequency power, and thus abnormal discharge is likely to be generated in the plasma producing chamber and the energy of ion acceleration is increased by an increase in the potential of plasma, which may damage an object formed on the substrate by plasma. Therefore, lowering the operation voltage of the applied high-frequency voltage is important, and reduction of the inductance of the antenna is required.

The document also describes that to suppress an increase in the inductance due to the increased size of the antenna, the antenna is constructed to be a linear conductor of a plane structure (two-dimensional structure) that is terminated without circling, which can reduce antenna inductance.
Non-patent document 1:
   Kanagawa-ken Sangyo Gijutu Sougou Kenkyusho Research Report No. 9/2003, pp 77-78
Patent document 1: JP2004-179658A
Patent document 2: JP2001-35697A

### DISCLOSURE OF THE INVENTION

### Object to be Achieved by the Invention

However, there still remains some problems even if the plasma CVD method is employed so that silicon dots and insulating films can be formed even at a relatively low temperature; the inductively coupled plasma CVD method in which the antenna disposed in the plasma producing chamber is used is employed to improve the efficiency of utilization of the input power and for other purposes; and an antenna with reduced inductance is employed to produce high-density plasma and form desired silicon dots and insulating films while suppressing abnormal discharge from the internal antenna and protecting the to-be-processed substrate, the silicon dots formed thereon and the insulating film from damages by plasma.

That is, according to the research conducted by the inventors of the present invention, plasma is not in a stable state immediately after it is ignited and abnormal discharge may be caused because of its instability after ignition. Some time is required for the plasma to become stable after being ignited. In addition, the time required for plasma to be stabilized varies each time the plasma is ignited even when the same plasma CVD apparatus is used and the same conditions for generating plasma such as the amount of the gas supplied, the input power, etc.

When the plasma starts to form silicon dots from the unstable status, the controllability of the particle diameter of the silicon dots is lowered, and an unallowable variation occurs in the particle diameter of the silicon dots between a plurality of substrates with silicon dots.

Moreover, when the plasma starts to form insulating films from the unstable status, the controllability of the film thickness is lowered, an unallowable variation in film thickness between a plurality of substrates with insulating films occurs.

For example, silicon dots and insulating films which can be utilized for semiconductor devices such as MOS capacitors and MOS-FETs have very small particle diameter of silicon dots and thickness of insulating films, for example, about 10 nm. Therefore, if the controllability of the particle diameter of the silicon dots and the thickness of the insulating film is lowered, silicon dots having a required particle diameter and insulating films having a required thickness cannot be formed with high reproducibility.

A first object of the present invention is to provide a method and an apparatus for forming silicon dots at a relatively low temperature, compared to the formation of silicon dots by the CVD method described in JP2004-179658A, which can suppress defects in silicon dots and clustering of silicon dots, which may occur at a high temperature, and damages to silicon dots by plasma, and can further form silicon dots with high controllability of the particle diameter of the silicon dots, and with high reproducibility between substrates.

A second object of the present invention is to provide a method and an apparatus for forming a substrate with silicon dots and insulating film, in which silicon dots and an insulating film can be formed at a relatively low temperature, which can suppress defects and clustering of silicon dots, which may occur at a high temperature, and damages to silicon dots and insulating film caused by plasma, and can further form silicon dots and insulating film with high controllability of the particle diameter of the silicon dots and high controllability of the thickness of the insulating film, and with high reproducibility between substrates.

### Means for Achieving the Object

The present invention provides the following method and apparatus for forming silicon dots to achieve the first object. Moreover, the present invention provides the following method and apparatus for forming a substrate with silicon dots and an insulating film to achieve the second object.

In the description provided below, the term “first” is a word used to distinguish a plasma producing chamber, an antenna and other components which are for forming silicon dots from those for forming an insulating film. Therefore, the plasma producing chamber, antenna and other components labeled with this term “first” indicates that they are for forming silicon dots.

In the description provided below, the term “second” is used to distinguish a plasma producing chamber, an antenna and other components for forming an insulating film from those for forming silicon dots. Therefore, the plasma producing chamber, antenna and other components labeled with the term “second” are for forming an insulating film.

(1) Method for Forming Silicon Dots

A method for forming silicon dots comprising applying high-frequency power to a first antenna with low inductance placed in a first plasma producing chamber to generate inductively coupled plasma from a gas for forming silicon dots supplied into the chamber, and forming silicon dots on a substrate disposed inside the chamber in the inductively coupled plasma, wherein in forming the silicon dots; while the plasma generated in the first plasma producing chamber is in an unstable state, the substrate is placed in such a state that the substrate is not exposed to the unstable plasma; and when the plasma is stabilized, the substrate is exposed to the stabilized plasma to start formation of silicon dots on the substrate.

(2) Apparatus for Forming Silicon Dots

An apparatus for forming silicon dots comprising:

a first plasma producing chamber;

a first gas supply device for supplying a gas for forming silicon dots into the first plasma producing chamber;

a first antenna with reduced inductance placed in the first plasma producing chamber;

a first high-frequency power applying device for generating inductively coupled plasma from the gas supplied from the first gas supply device by applying high-frequency power to the first antenna;

a first plasma state managing device which, in forming the silicon dots, places a substrate on which silicon dots are to be formed disposed in the first plasma producing chamber in a state that the substrate is not exposed to unstable plasma while the plasma in the first plasma producing chamber is unstable and exposes the substrate to stabilized plasma when the plasma is stabilized;

a first plasma state detecting device which detects the state of the plasma in the first plasma producing chamber; and

a first controller for controlling the first plasma state managing device in such a manner that the substrate is placed in a state that the substrate is not exposed to unstable plasma when the state of the plasma generated in the first plasma producing chamber detected by the first plasma state detecting device is unstable, and the substrate is exposed to stabilized plasma when the plasma is stabilized.

(3) Method for Forming Substrate with Silicon Dots and Insulating Film

A method for forming a substrate with silicon dots and an insulating film, wherein

the silicon dots are formed at least once and the insulating film is formed at least once on a substrate,

the silicon dots are formed by the method for forming silicon dots according to the present invention,

the insulating film is formed by employing a method in which high-frequency power is applied to a second antenna with reduced inductance placed in a second plasma producing chamber to generate inductively coupled plasma from a gas for forming an insulating film supplied into the second chamber and an insulating film is formed in the inductively coupled plasma on the substrate disposed in the second chamber, in forming an insulating film according to the method for forming an insulating film, the substrate is placed in a state that it is not exposed to unstable plasma while the plasma generated in the second plasma producing chamber is unstable, and the substrate is exposed to stabilized plasma when the plasma is stabilized to start forming an insulating film on the substrate,

when the insulating film is formed after the silicon dots are formed, the substrate is transferred from a chamber (the first plasma producing chamber or a terminally treating chamber described later, if used) where the substrate is present to the second plasma producing chamber via a substrate transferring path (substrate transferring path which brings the first and second plasma producing chambers into communication, or substrate transferring path which brings the terminally treating chamber described later and the second plasma producing chamber into communication directly or via the first plasma producing chamber, when the terminally treating chamber is used, etc.) which brings the two chambers into communication in an airtight fashion with respect to an ambient air, and when the silicon dots are formed after the insulating film is formed, the substrate is transferred from the second plasma producing chamber to the first plasma producing chamber via a substrate transferring path (the substrate transferring path which brings the second plasma producing chamber into communication with the first plasma producing chamber directly or via the terminally treating chamber described later, etc.) which brings the two chambers into communication in an airtight fashion with respect to an ambient air.

(4) Apparatus for Forming a Substrate with Silicon Dots and Insulating Film

An apparatus for forming a substrate with silicon dots and an insulating film, the apparatus comprising the apparatus for forming silicon dots according to the present invention and an apparatus for forming insulating film, the apparatus for forming insulating film comprising:

a second plasma producing chamber;

a second gas supply device which supplies a gas for forming an insulating film into the second plasma producing chamber;

a second antenna with reduced inductance placed in the second plasma producing chamber;

a second high-frequency power applying device for applying high-frequency power to the second antenna to produce inductively coupled plasma from the gas supplied from the second gas supply device into the second plasma producing chamber;

a second plasma state managing device which, in forming the insulating film, places an insulating film formation target substrate disposed in the second plasma producing chamber in a state that the substrate is not exposed to unstable plasma while the plasma in the second plasma producing chamber is unstable and exposes the substrate to stabilized plasma when the plasma is stabilized;

a second plasma state detecting device for detecting the state of the plasma produced in the second plasma producing chamber, and

a second controller for controlling the second plasma state managing device in such a manner that the substrate is placed in a state that the substrate is not exposed to unstable plasma when the state of the plasma generated in the second plasma producing chamber detected by the second plasma state detecting device is unstable, and the substrate is exposed to stabilized plasma when the plasma is stabilized, and

the first plasma producing chamber and the second plasma producing chamber being in communication via a substrate transferring path for transferring the substrate between the two chambers in an airtight fashion with respect to an ambient air.

The term “silicon dot” used herein is generally that having a very small particle diameter of about 1 nm to 10 nm in general.

Moreover, the insulating film generally has a thickness of, for example, about 1 nm to 100 nm, and more preferably about 2 nm to 20 nm.

Moreover, the term “antenna with reduced inductance” means an antenna which has inductance lower than a large antenna circling around the plasma producing region in the plasma producing chamber. This is a relatively short antenna which is opposed to a plasma producing region in the plasma producing chamber, and has an end terminated without circling around the plasma producing region. Typical examples include a U-shaped antenna. The U-shaped antennas include, as well as literally U-shaped antennas, gate-shaped or square U-shaped antennas, semicircular and other arc-shaped antennas, antennas in such shapes made up of straight-line portions and arc-shaped portions, among others.

The antenna with reduced inductance has an inductance L of, for example, about 200×10⁻⁹ [H] to 230×10⁻⁹ [H] or lower. When the frequency of high-frequency power input to the antenna is 13.56 MHz, impedance |Z| is about 450 or lower, and further about 18Ω to 20Ω or lower, for example.

Moreover, the “plasma state detecting device” may be any device as long as it can detect whether plasma is unstable or stable. Typical examples include devices which can detect whether plasma is unstable or stable based on the spectral intensity of the light emitted from the plasma.

According to the method and apparatus for forming silicon dots of the present invention, silicon dots can be formed by the internal antenna type inductively coupled plasma CVD method even at a relatively low temperature of about 250° C. or lower while suppressing the occurrence of defects and clustering of silicon dots which may occur at a high temperature, and high-density plasma is formed and yet damages to the substrate and silicon dots formed thereon caused by plasma are suppressed by employing an internal antenna (first antenna) with reduced inductance in the first plasma producing chamber.

Moreover, in forming the silicon dots, since the substrate is placed in such a state that it is not exposed to unstable plasma while the plasma generated in the first plasma producing chamber is unstable, and when the plasma is stabilized, the substrate is exposed to the stabilized plasma to start forming silicon dots on the substrate. Therefore, silicon dots can be formed with high controllability of the particle diameter of the silicon dots and high reproducibility between substrates.

According to the method and apparatus for forming a substrate with silicon dots and an insulating film of the present invention, since the method for forming silicon dots and apparatus for forming silicon dots described above are employed, respectively, silicon dots can be formed at a relatively low temperature while suppressing the occurrence of defects and clustering of silicon dots which may occur at a high temperature, and suppressing damages caused by plasma. Moreover, silicon dots can be formed with high controllability of the particle diameter of the silicon dots and high reproducibility between substrates.

An insulating film can be also formed even at a relatively low temperature of about 250° C. or lower by the internal antenna type inductively coupled plasma CVD method, since high-density plasma is formed by employing an internal antenna (second antenna) with reduced inductance placed in the second plasma producing chamber and yet damages to the insulating film caused by plasma or damages to silicon dots, which may be formed earlier, are suppressed.

Moreover, in forming an insulating film, since the substrate is placed in a state that it is not exposed to plasma while the plasma generated in the second plasma producing chamber is unstable, and the substrate is exposed to plasma when the plasma is stabilized to start forming an insulating film on the substrate, an insulating film can be formed with high controllability of the thickness of the insulating film and high reproducibility between substrates.

When the insulating film is formed after the silicon dots are formed, the substrate is transferred from a chamber in which the substrate is present (the first plasma producing chamber or a terminally treating chamber described later, if used) to the second plasma producing chamber via a substrate transferring path which brings the two chambers into communication in an airtight fashion with respect to an ambient air, and when the silicon dots are formed after the insulating film is formed, the substrate is transferred from the second plasma producing chamber to the first plasma producing chamber via a substrate transferring path which brings the two chambers into communication in an airtight fashion with respect to an ambient air (the apparatus allows such transportation). Therefore, the already formed silicon dots and the insulating film are prevented from deposition or contamination of undesired impurities in the atmosphere, and a substrate with good silicon dots and insulating film can be provided accordingly.

(5) Further Description Concerning Method and Apparatus for Forming Silicon Dots

In the method for forming silicon dots according to the present invention, silicon dots are formed in a state that the plasma in the first plasma producing chamber is stabilized. In such a case, for example,

the following constitution may be employed: an openable and closable shutter device for shielding the substrate disposed in the first plasma producing chamber from the plasma produced in the chamber is provided, and in forming the silicon dots, the substrate is shielded from the plasma by the shutter device to avoid exposure to unstable plasma until the plasma in the first plasma producing chamber is stabilized, and the shutter device is opened to start forming silicon dots on the substrate in plasma when the plasma is stabilized.

As another method, for example, the following constitution may be employed: a substrate retracting device for retracting the substrate disposed in the first plasma producing chamber from the plasma produced in the chamber is provided, and in forming the silicon dots, the substrate is retracted from the plasma to avoid exposure to unstable plasma by the substrate retracting device until the plasma in the first plasma producing chamber is stabilized, and when the plasma is stabilized, the substrate is disposed in a position where it is exposed to the stabilized plasma by the substrate retracting device to start forming silicon dots on the substrate.

In any of the above structures, in the method for forming silicon dots according to the present invention, the unstable state and stable state of the plasma produced in the first plasma producing chamber may be detected, for example, by a plasma state detecting device provided for the first plasma producing chamber.

Moreover, the apparatus for forming silicon dots according to the present invention may comprise a first controller which controls the first plasma state managing device in such a manner that the substrate is placed in a state that it is not exposed to plasma when the state of plasma in the first plasma producing chamber detected by the first plasma state detecting device is unstable, and the substrate is exposed to plasma when the plasma is stabilized.

Examples of devices which can be employed as the first plasma state managing device include an openable and closable shutter device which shields the substrate disposed in the first plasma producing chamber from the plasma produced in the plasma producing chamber or exposes the same to the plasma, a substrate retracting device which retracts the substrate disposed in the first plasma producing chamber from the plasma produced in the first plasma producing chamber or transfers the substrate from a retracted position to a position where the substrate is exposed to the plasma, among others.

When the shutter device is employed, the first controller may be so constructed that in forming the silicon dots on the substrate, the first controller controls the shutter device in such a manner that the substrate is shielded from the plasma by the shutter device to avoid exposure to unstable plasma until the plasma in the first plasma producing chamber is stabilized, and the shutter device is opened to start forming silicon dots on the substrate in plasma when the plasma is stabilized.

When the substrate retracting device is employed, the first controller may be so constructed that in forming the silicon dots on the substrate, the first controller controls the substrate retracting device in such a manner that the substrate retracting device retracts the substrate from the plasma to prevent the substrate from being exposed to unstable plasma until the plasma in the first plasma producing chamber is stabilized, and the substrate retracting device places the substrate in a position where it is exposed to stabilized plasma when the plasma is stabilized.

In the method for forming silicon dots according to the present invention, for example, the following procedure is conducted: in forming the silicon dots, a silane-based gas and hydrogen gas are supplied into the first plasma producing chamber as the gases for forming silicon dots; the inductively coupled plasma is produced from these gases; the substrate is placed in a state that it is not exposed to unstable plasma while the plasma is unstable; and the substrate is exposed to stabilized plasma to start forming silicon dots on the substrate when the plasma is stabilized.

Moreover, the following procedure can be also conducted: a silicon sputter target is placed in the first plasma producing chamber in advance; in forming the silicon dots, a gas for sputtering is supplied into the first plasma producing chamber as the gas for forming silicon dots to produce the inductively coupled plasma from the gas for sputtering; the substrate is placed in a state that it is not exposed to unstable plasma while the plasma is unstable, and the substrate is exposed to stabilized plasma when the plasma is stabilized; and formation of silicon dots on the substrate is started by chemical sputtering of the silicon sputter target with the stabilized plasma.

In this case, as the “silicon sputter target”, commercially available silicon wafers, materials produced by forming a silicon film on the target substrate, among others, can be employed. The silicon sputter targets produced by forming a silicon film on the target substrate may be processed, for example, in the following manner: a silicon film is formed on the target substrate by a film forming apparatus (for example, a plasma CVD apparatus such as an inductively coupled plasma CVD apparatus) which is independent of the apparatus for forming silicon dots or is in communication with the first plasma producing chamber of the apparatus for forming silicon dots in an airtight fashion with respect to an ambient air (without exposing to the outside air), and the thus-obtained silicon sputter target is transferred to and placed in the first plasma producing chamber.

Moreover, prior to the formation of the silicon dots, the following procedure may be conducted: a gas for forming silicon film is supplied into the first plasma producing chamber to produce plasma from the gas by applying high-frequency power to the first antenna; a silicon film is formed on a member on which a silicon film is to be formed in the first plasma producing chamber in the plasma; in forming the silicon dots, a gas for sputtering is supplied into the first plasma producing chamber as the gas for forming silicon dots to produce the inductively coupled plasma from the gas for sputtering; the substrate is placed in a state that it is not exposed to unstable plasma while the plasma is unstable; and the substrate is exposed to stabilized plasma when the plasma is stabilized; and formation of silicon dots on the substrate is started by chemical sputtering of the silicon film with the stabilized plasma.

The term “a member on which a silicon film is to be formed in the first plasma producing chamber” used herein means at least one of the inner wall of the first plasma producing chamber and the target substrate which may be placed in the first plasma producing chamber.

Moreover, the “gas for forming silicon film” may be the same as the “gas for forming silicon dots” in terms of the type of gas. Typical examples of the gas for forming silicon film include gases comprising both a silane-based gas and hydrogen gas.

Typical examples of the gas for sputtering include hydrogen gas.

In relation to the several examples of silicon dot formation in the method for forming silicon dots described above, the following construction may be employed in the apparatus for forming silicon dots according to the present invention.

That is, for example, the apparatus for forming silicon dots may be so constructed that the first gas supply device supplies a silane-based gas and hydrogen gas as the gases for forming silicon dots into the first plasma producing chamber.

Alternatively, a silicon sputter target may be placed in the first plasma producing chamber, and the first gas supply device may supply the gas for sputtering which is used for chemical sputtering of the silicon sputter target by being changed into plasma as the gas for forming silicon dots into the first plasma producing chamber.

Furthermore, a device for supplying gas for forming silicon film may be provided, which supplies, into the first plasma producing chamber, a gas for forming silicon film which forms a silicon film by being changed into plasma on the member on which a silicon film is to be formed in the first plasma producing chamber prior to the formation of the silicon dots, and the first gas supply device may supply the gas for sputtering which is used for chemical sputtering of the silicon film by being changed into plasma as the gas for forming silicon dots into the first plasma producing chamber.

It is desirable that the silicon dots are terminally treated with oxygen, nitrogen or other substances on their surfaces. The term “terminating treatment with oxygen, nitrogen or other substances” used herein means that oxygen or nitrogen is bound to the surfaces of the silicon dots so that (Si—O) bonds, (Si—N) bonds, or (Si—O—N) bonds are formed.

The oxygen bonds or nitrogen bonds formed by such terminating treatment can function to compensate a defect, e.g., uncombined dangling bond, on the surfaces of the terminally untreated silicon dots and can give a high-quality dot state in which the defect is substantially suppressed as a whole. When employed as electronic device materials, the silicon dots so terminally treated can achieve improvements in the properties required of the electronic devices. For example, when used as a TFT material, the silicon dots can improve the electron mobility in TFTs and can reduce OFF-current. Moreover, the silicon dots can improve reliability, such as resistance to changes in the voltage-current characteristics even when used in TFTs for a long period of time.

In the method for forming silicon dots according to the present invention, the surfaces of the silicon dots may be terminally treated in the plasma for terminating treatment produced by applying high-frequency power to at least one gas for terminating treatment selected from an oxygen-containing gas and a nitrogen-containing gas after the silicon dots are formed.

This terminating treatment may be carried out in the first plasma producing chamber, or the substrate on which the silicon dots are formed may be loaded into a terminally treating chamber which is in communication with the first plasma producing chamber after the silicon dots are formed in the first plasma producing chamber, and may be subjected to the terminating treatment in the terminally treating chamber.

In relation to this, the apparatus for forming silicon dots according to the present invention may further comprise a device for supplying gas for terminating treatment which supplies at least one gas for terminating treatment selected from an oxygen-containing gas and a nitrogen-containing gas into the first plasma producing chamber after the silicon dots are formed.

Alternatively, the apparatus for forming silicon dots according to the present invention may further comprise a terminally treating chamber which is in communication with the first plasma producing chamber in such a manner that the substrate on which silicon dots are formed in the first plasma producing chamber can be loaded thereinto, and subjects the silicon dots on the substrate transferred from the first plasma producing chamber to a terminating treatment in the plasma for terminating treatment produced by applying high-frequency power to at least one gas for terminating treatment selected from an oxygen-containing gas and a nitrogen-containing gas.

In either structure, when the terminating treatment is conducted, a terminating treatment may be carried out in the stabilized gas plasma for terminating treatment by using the plasma state managing device as mentioned above or by other means.

Examples of the oxygen-containing gas for terminating treatment include oxygen gas and nitrogen oxide (N₂O) gas. Examples of the nitrogen-containing gas include nitrogen gas and an ammonia (NH₄) gas.

In either case, the method and apparatus for forming silicon dots according to the present invention can be used in not only the case where the insulating film and other components are formed on the silicon dots, but also in the case where only the silicon dots are formed.

(6) Further Description Concerning the Method and Apparatus for Forming a Substrate with Silicon Dots and Insulating Film

In the method for forming substrate with silicon dots and insulating film according to the present invention, in forming the insulating film, the insulating film is formed in a state that the plasma in the second plasma producing chamber is stabilized. In such a case, the following example may be employed:

an openable and closable shutter device for shielding the substrate disposed in the second plasma producing chamber from the plasma produced in the second plasma producing chamber is provided; in forming an insulating film, the substrate is shielded from the plasma by the shutter device to avoid exposure to unstable plasma until the plasma in the second plasma producing chamber is stabilized; and the shutter device is opened to start forming an insulating film on the substrate in stabilized plasma when the plasma is stabilized.

Moreover, the following another method may be employed: a substrate retracting device which retracts the substrate disposed in the second plasma producing chamber from the plasma produced in the second plasma producing chamber is provided; in forming an insulating film, the substrate is retracted from the plasma to avoid exposure to unstable plasma by the substrate retracting device until the plasma in the second plasma producing chamber is stabilized; and the substrate is disposed in a position where it is exposed to stabilize plasma by the substrate retracting device to start forming the insulating film on the substrate when the plasma is stabilized.

In either case, the unstable state and stable state of the plasma produced in the second plasma producing chamber can be detected, for example, by a plasma state detecting device provided for the second plasma producing chamber.

Moreover, the substrate may be supported by a substrate holder having a substrate heater, and in forming the insulating film after the silicon dots are formed, when the substrate is transferred from the chamber where the substrate is present to the second plasma producing chamber side through the substrate transportation path, and in forming the silicon dots after the insulating film is formed, when the substrate is transferred from the second plasma producing chamber to the first plasma producing chamber side through the substrate transportation path, the substrate may be transferred together with the substrate holder.

In such a manner, the substrate can be quickly heated to a desired temperature in the next silicon dot formation or insulating film formation than in the case where the substrate is removed from the substrate holder for transportation.

In relation to this, in the apparatus for forming silicon dots and insulating film according to the present invention, a substrate holder having a substrate heater and a transferring device for the substrate holder may be provided. The apparatus for forming silicon dots and insulating film may be so constituted that in forming the insulating film after the silicon dots are formed, when the substrate holder transferring device transfers the substrate from the first plasma producing chamber to the second plasma producing chamber side through the substrate transportation path, and in forming the silicon dots after the insulating film is formed, when the substrate is transferred from the second plasma producing chamber to the first plasma producing chamber side through the substrate transportation path, the substrate may be transferred together with the substrate holder.

When the substrate holder having a substrate heater is employed in supporting the substrate and the substrate retracting device as mentioned above is employed in silicon dot formation and insulating film formation, retracting the substrate and depositing the same in a position where it is exposed to plasma may be conducted by retracting the substrate together with the substrate holder by which it is supported, or disposing the substrate in a position where it is exposed to the plasma together with the substrate holder, by the substrate retracting device.

In either case, the type of the insulating film in forming the insulating film include those produced by for example, introducing a silane-based gas and oxygen gas as the gases for forming an insulating film into the second plasma producing chamber, producing the inductively coupled plasma from these gases, placing the substrate in a state that it is not exposed to unstable plasma while the plasma is unstable, exposing the substrate to plasma when the plasma is stabilized to start formation of a silicon oxide insulating film on the substrate.

In relation to this, in the apparatus for forming a substrate with silicon dots and insulating film according to the present invention, the second gas supply device of the apparatus for forming insulating film may supply the silane-based gas and oxygen gas for forming silicon oxide insulating film as the gases for forming an insulating film into the second plasma producing chamber.

With regard to forming the insulating film, the apparatus for forming a substrate with silicon dots and insulating film according to the present invention comprises a second controller which controls the second plasma state managing device so as to place the substrate in a state that it is not exposed to unstable plasma when the state of the plasma in the second plasma producing chamber detected by the second plasma state detecting device is unstable, and expose the substrate to stabilized plasma when the plasma is stabilized.

In this case, examples of the second plasma state managing device include an openable and closable shutter device which shields the substrate disposed in the second plasma producing chamber from the plasma produced in the plasma producing chamber or exposes the same to the plasma, and a substrate retracting device which retracts the substrate disposed in the second plasma producing chamber from the plasma produced in the second plasma producing chamber or transfers the substrate from a retracted position to a position where it is exposed to the plasma.

When the shutter device is employed, the second controller may be so constituted to control the shutter device, in forming the insulating film on the substrate, in a manner of shielding the substrate from the plasma by the shutter device to avoid exposure of the substrate to unstable plasma until the plasma in the second plasma producing chamber is stabilized, and opening the shutter device so that formation of an insulating film on the substrate is started in stabilized plasma when the plasma is stabilized.

When the substrate retracting device is employed, the second controller may control, in forming the insulating film on the substrate, the substrate retracting device in such a manner that the substrate retracting device retracts the substrate from the plasma to prevent the substrate from being exposed to unstable plasma until the plasma in the second plasma producing chamber is stabilized, and placing the substrate in a position where it is exposed to stabilized plasma when the plasma is stabilized.

### Effect of the Invention

As already mentioned, the present invention can provide a method and an apparatus for forming silicon dots which can form silicon dots at a relatively low temperature, suppress defects and clustering of silicon dots, which may be generated at a high temperature, and damages to silicon dots caused by plasma, and can further form silicon dots with high controllability of the particle diameter of the silicon dots, and with high reproducibility between substrates.

The present invention can also provide a method and an apparatus for forming a substrate with silicon dots and insulating film at a relatively low temperature, which can suppress defects and clustering of silicon dots, which may occur at a high temperature, and damages to silicon dots and insulating film caused by plasma, and further with high controllability of the particle diameter of the silicon dots and high controllability of the thickness of the insulating film, and with high reproducibility between substrates.

### BRIEF DESCRIPTION OF THE DRAWINGS

FIG. 1 shows an example of the apparatus for forming a substrate with silicon dots and insulating film according to the present invention.

FIG. 2 shows shape, dimension and other properties of an antenna.

FIG. 3A shows a state that a shutter device is closed.

FIG. 3B shows a state that a shutter device shown in FIG. 3A is opened.

FIG. 3C shows another example of shutter device.

FIG. 4 is a block diagram which shows an example of a control circuit of the shutter device.

FIG. 5 shows part of the step of forming silicon dots by the apparatus in FIG. 1.

FIG. 6 shows the rest of the step of forming the silicon dots by the apparatus in FIG. 1.

FIG. 7 shows part of the step of forming an insulating film by the apparatus in FIG. 1.

FIG. 8 shows the rest of the step of forming the insulating film by the apparatus in FIG. 1.

FIG. 9 shows another example of the apparatus for forming a substrate with silicon dots and insulating film according to the present invention.

FIG. 10 is a block diagram which shows an example of a control circuit of the substrate retracting device.

FIG. 11 shows the step of forming silicon dots by the apparatus in FIG. 9.

FIG. 12 shows the step of forming an insulating film by the apparatus in FIG. 9.

FIG. 13 shows the results of an experiment indicating that it takes some time for plasma to be stabilized from the ignition of plasma.

FIG. 14 shows that a silicon oxide film formed by the method according to the present invention has a current-voltage characteristic as high as that of a silicon oxide film formed by a conventional method.

FIG. 15 shows yet another example of the apparatus for forming a substrate with silicon dots and insulating film according to the present invention.

FIG. 16A shows an example of a semiconductor apparatus utilizing silicon dots.

FIG. 16B shows an example of a semiconductor apparatus utilizing two-layer silicon dots.

### DESCRIPTION OF THE SYMBOLS

A, A′ Apparatus for forming a substrate with silicon dots and insulating film
1, 1′ Apparatus for forming silicon dots
11 First plasma producing chamber
111 Top wall
12 First antenna
13 Busbar
14 Matching box
15 High-frequency power source
16, 19 Substrate holder
161, 191 Heater
100 Substrate holder supporting base
17 Exhaust device
18 Plasma state grasping device
G1 Silane-based gas supply device
G2 Hydrogen gas supply device
10 Shutter device
s1, S2, s1′, S2′ Shutter blade
g1 to g4 Gear
M Motor
S Substrate
2, 2′ Apparatus for forming insulating film
21 Second plasma producing chamber
211 Top wall
22 First antenna
23 Busbar
24 Matching box
25 High-frequency power source
26 Substrate holder
261 Heater
200 Substrate holder supporting base
28 Plasma state grasping device
G3 Silane-based gas supply device
G4 Oxygen gas supply device
20 Shutter device
3, 3′ Substrate transferring path
V1, V2 Gate valve
31 Substrate transferring robot
41, 42 Shutter device control unit
51, 52 Motor drive circuit
31′ Substrate retracting device
4′ Substrate retracting device control unit
5′ Substrate retracting device drive circuit

### BEST MODE FOR IMPLEMENTING THE INVENTION

Embodiments of the present invention will be described below with reference to drawings.

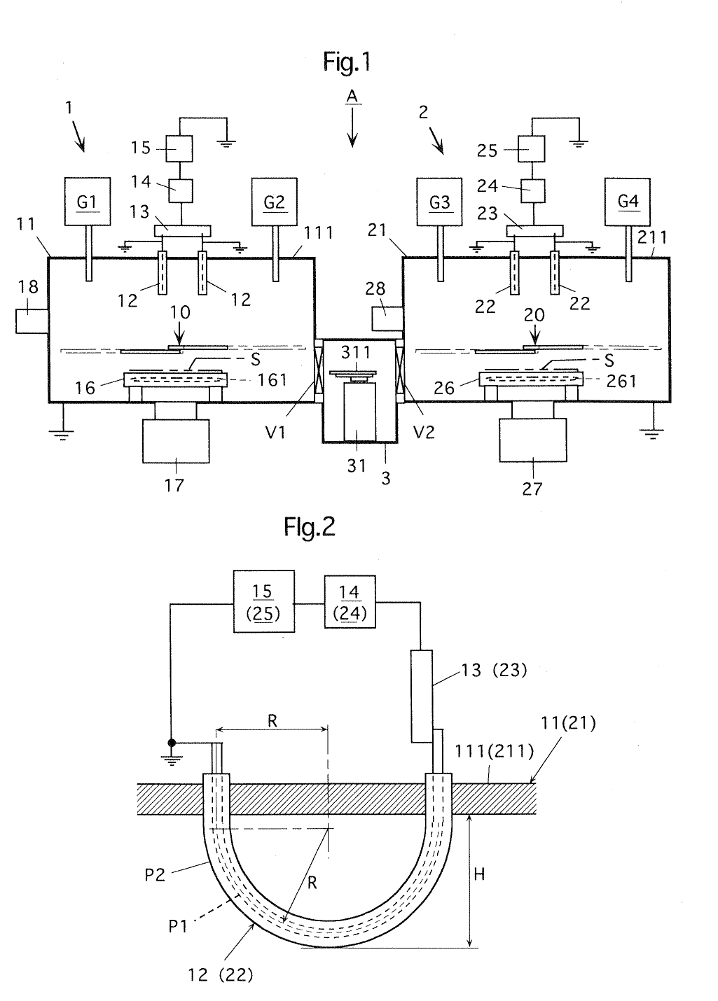

FIG. 1 shows an apparatus A for forming a substrate with silicon dots and insulating film comprising an apparatus 1 for forming silicon dots and an apparatus 2 for forming insulating film.

The apparatus 1 for forming silicon dots comprises a first plasma producing chamber 11, in which two antennas 12 are placed next to each other, and a substrate holder 16 supporting a to-be-processed substrate S is provided below the antennas 12. The substrate holder 16 comprises a heater 161 which heats the substrate S supported thereby.

Each of the antennas 12 protrudes to the outside of the chamber through a top wall 111 of the plasma producing chamber 11 at its one end. One end of the portion protruding to the outside of the chamber of each of these two antennas 12 is connected to a busbar 13, and the busbar 13 is connected to an output-variable high-frequency power source 15 via a matching box 14. The other end of the portion protruding to the outside of the chamber of each of the two antennas 12 is grounded. The details of the antennas 12 will be described later.

A gas supply device G1 for supplying a silane-based gas into the plasma producing chamber 11 is connected to the chamber, and a gas supply device G2 which supplies hydrogen gas into the chamber is connected to the plasma producing chamber 11. Examples of usable silane-based gas include monosilane (SiH₄) gas and disilane (Si₂H₆) gas.

In this example, these silane-based gas and hydrogen gas are gases for forming silicon dots, and the gas supply devices G1 and G2 constitute a first gas supply device which supplies the gases for forming silicon dots into the plasma producing chamber 11.

Moreover, an exhaust device 17 which exhausts a gas from the plasma producing chamber 11 to reduce the pressure inside the chamber is also connected to the chamber.

Furthermore, the plasma producing chamber 11 is provided with a plasma state detecting device 18 for detecting the state of inductively coupled plasma formed in the manner described later.

The apparatus 2 for forming insulating film comprises a second plasma producing chamber 21, in which two antennas 22 are placed next to each other, and a substrate holder 26 which supports a to-be-processed substrate S is provided below the antennas 22. The substrate holder 26 comprises a heater 261 which heats the substrate S supported thereby.

The antennas 22 have the same shape and dimension as the antennas 12, and as the antennas 12, their both ends protrude to the outside of the plasma producing chamber 21 through a top wall 211 of the chamber 21. One end of the portion protruding to the outside of the chamber of each of the antennas 22 is connected to a busbar 23, and the busbar 23 is connected to an output-variable high-frequency power source 25 via a matching box 24. The other end of the portion protruding to the outside of the chamber of each of the antennas 22 is grounded. The details of the antennas 22 will be described later.

A gas supply device G3 for supplying a silane-based gas into the chamber is connected to the plasma producing chamber 21, and a gas supply device G4 which supplies oxygen gas into the chamber is also connected to the plasma producing chamber 21. Examples of usable silane-based gas include monosilane (SiH₄) gas and a disilane (Si₂H₆) gas.

In this example, these silane-based gas and oxygen gas are gases for forming a silicon oxide (SiO₂) film, which is an insulating film, and the gas supply devices G3 and G4 constitute the second gas supply device which supplies the gases for forming insulating film into the plasma producing chamber 21.

Moreover, an exhaust device 27 which exhausts a gas from the chamber to reduce the pressure inside the chamber is also connected to the plasma producing chamber 21.

Furthermore, the plasma producing chamber 21 is provided with a plasma state detecting device 28 for detecting the state of inductively coupled plasma formed in the manner described later.

As shown in FIG. 2, each of the antennas 12 (22) is a copper pipe P1 having an outer diameter of ¼ inches (6.35 mm) and a wall thickness of about 1 mm covered with an insulating pipe P2 made of alumina having an outer diameter of 20 mm and a wall thickness of 3 mm, and has a shape made up of a semicircular portion (radius of curvature of the center axis of the copper pipe P1: R=50 mm) and straight line portions continuously connected to both ends of the semicircular portion.

The straight line portions of each of the antennas 12 (22) extend through the top wall 111 (211) of the plasma producing chamber 11 (21) in an airtight fashion.

A height H from the lower end of each of the antennas 12 (22) to the top wall 111 (211) in the plasma producing chamber 11 (21) is 75 mm.

The intervals of the two antennas 12 and the two antennas 22 in the plasma producing chamber are both 100 mm.

Each of the antennas 12 (22) has an inductance lower than a large antenna which circles around a plasma producing region in the plasma producing chamber. When the two antennas 12 (22) are used and placed next to each other as illustrated, the total inductance L of the two antennas is about 150×10⁻⁹ [H] to about 200×10⁻⁹ [H], and when the frequency of the applied high-frequency power is 13.56 MHz, the total impedance |Z| of the two antennas is about 12Ω to about 18Ω.

The higher the number of antennas, the lower the inductance and impedance.

The plasma state detecting devices 18, 28 have the same constitution. In this example, whether the plasma is in an unstable state or is stabilized can be detected based on the spectral intensity of the light emitted from plasma.

Stated more specifically, in plasma, the gas is decomposed and produces various kinds of atoms, ions, radicals and the like, as well as light emission. By spectroscopically analyzing the emitted light and grasping the spectral intensity of the plasma species which indicates that decomposition of the gas is not sufficiently proceeded or sufficiently proceeded, in other word, that the plasma is not stabilized yet or is stabilized, whether the plasma is in an unstable state or a stabilized state can be detected.

Specific examples of the plasma state detecting device include a fiber optic spectrometer (model: USB2000, measurement targets: light-emitting atoms, light-emitting ions) manufactured by Ocean Optics, Inc., USA, a 45° sector field high transmission ion energy analyzer/quadrupole mass analyzer (model: HAL EQP500, measurement target: cations, anions, radicals, neutral particles) manufactured by Hiden Analytical Ltd, UK, among others.

In the plasma producing chamber 11, an openable and closable shutter device 10 which covers the to-be-processed substrate S supported on the substrate holder 16 from above to shield the substrate from plasma is further provided, and in the plasma producing chamber 21, the openable and closable shutter device 20 which can cover the to-be-processed substrate S supported on the substrate holder 26 from above to shield the substrate from the plasma is further provided.

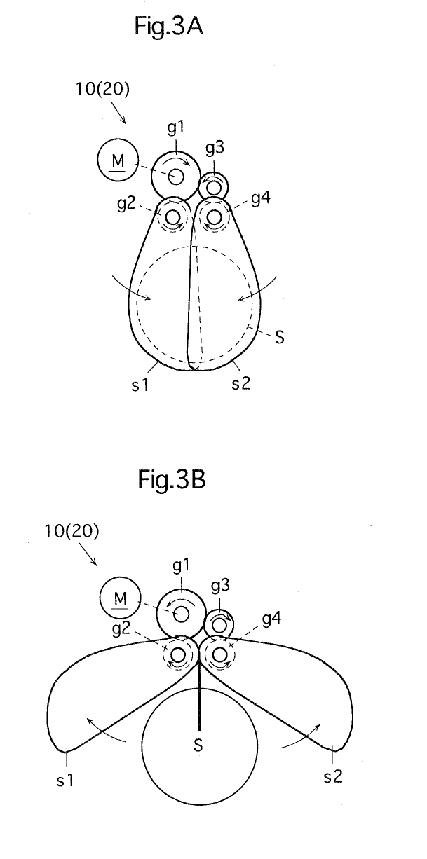

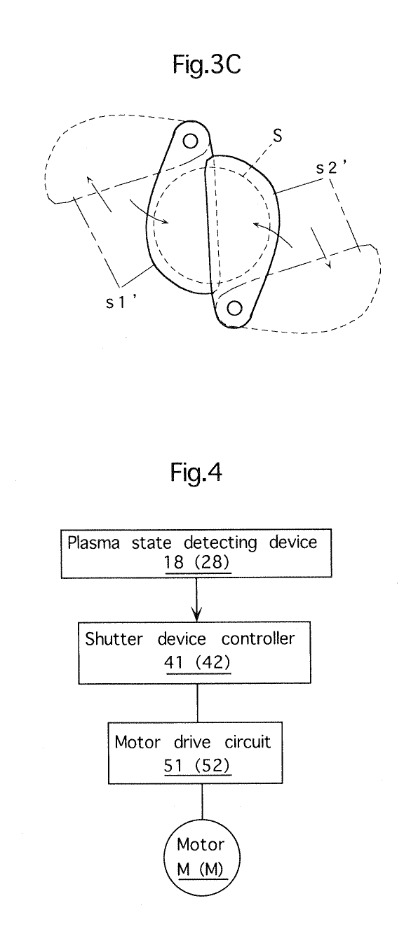

These shutter devices 10, 20 have the same structure, and have a pair of shutter blades s1, s2, as shown in FIGS. 3A and 3B, in which one of the shutter blades, s1, can be opened and closed by a motor M which is forwardly and reversely rotatable via gear trains g1 and g2, and the other shutter blade s2 can be opened and closed via gear trains g1, g3 and g4. Thus, the shutter blades s1,s2 can be opened and closed.

As shown in FIG. 3A, the shutter blades s1, s2 are closed by being moved towards each other, whereby the substrate S on the substrate holder 16 (26) is shielded from the plasma, and as shown in FIG. 3B, the shutter blade s1, s2 are opened by being moved away from each other, whereby the substrate S on the substrate holder 16 (26) can be exposed to the plasma.

The shutter device is not limited to that mentioned above. For example, as shown in FIG. 3C, it may have such a structure that has shutter blades s1', s2′ which can be opened and closed around the axis on both outer sides of the substrate S in the diametrical direction of the substrate S.

Although not shown in FIG. 1, the shutter device 10 in the apparatus 1 for forming silicon dots is provided with a shutter controller 41, as shown in FIG. 4, and while the information that the plasma formed in the plasma producing chamber 11 is in an unstable state is transmitted from the plasma state detecting device 18 to the controller 41, the controller 41 instructs the motor drive circuit 51 to keep the shutter blades s1, s2 closed, and when the information that the plasma is stabilized is transmitted from the plasma state detecting device 18 to the controller 41, the controller 41 instructs the motor drive circuit 51 to open the shutter blades s1, s2.

The shutter device 20 in the apparatus for forming insulating film is also provided with a shutter controller 42. While the information that the plasma formed in the plasma producing chamber 21 is in an unstable state is transmitted from the plasma state detecting device 28 to the controller 42, the controller 42 instructs the motor drive circuit 52 to keep the shutter blades s1, s2 closed, and when the information that the plasma is stabilized is transmitted from the plasma state detecting device 28 to the controller 42, the controller 42 instructs the motor drive circuit 52 to open the shutter blades s1, s2.

The plasma producing chamber 11 of the apparatus 1 for forming silicon dots and the plasma producing chamber 21 of the apparatus 2 for forming insulating film are communicated by a substrate transferring path 3 in an airtight fashion with respect to an ambient air. An openable and closable gate valve V1 which can shut off the chamber 11 from the path 3 in an airtight fashion is provided between the path 3 and the chamber 11, and an openable and closable gate valve V2 which can shut off the chamber 21 from the path 3 in an airtight fashion is provided between the path 3 and the chamber 21.

A substrate transferring robot 31 is placed inside the path 3. The robot 31 comprises a substrate transferring arm 311 which is capable of elevating, descending, positing, extending and retracting, and the substrate S supported on the substrate holder 16 in the chamber 11 can be disposed on the substrate holder 26 in the chamber 21 by the robot, or the substrate S supported on the substrate holder 26 in the chamber 21 can be disposed on the substrate holder 16 in the chamber 11 by the robot. As such a substrate transferring robot, a commercially available substrate transferring robot can be utilized.

Example 1 will be described below, in which a substrate with silicon dots and insulating film which can be utilized for forming a semiconductor device having a MOS capacitor and a MOSFET structure and the like shown in FIG. 16A as an example is formed by using the apparatus A for forming the substrate with silicon dots and insulating film described above. A fiber optic spectrometer manufactured by Ocean Optics, Inc., USA (model: USB2000) was employed as the plasma state detecting devices 18, 28.

### Example 1

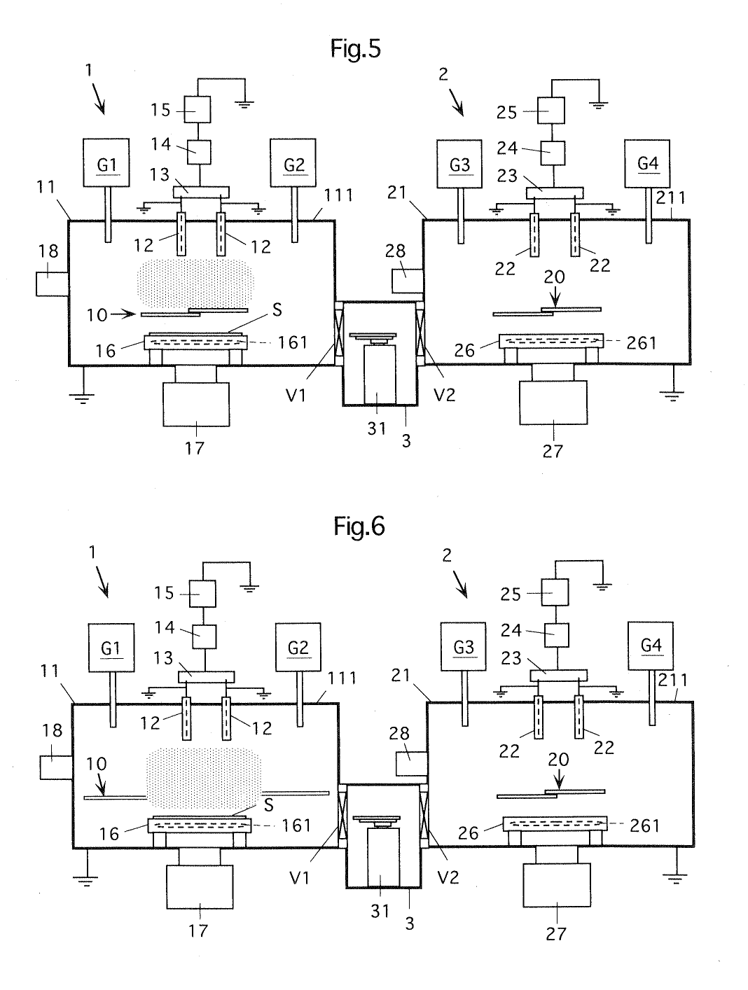

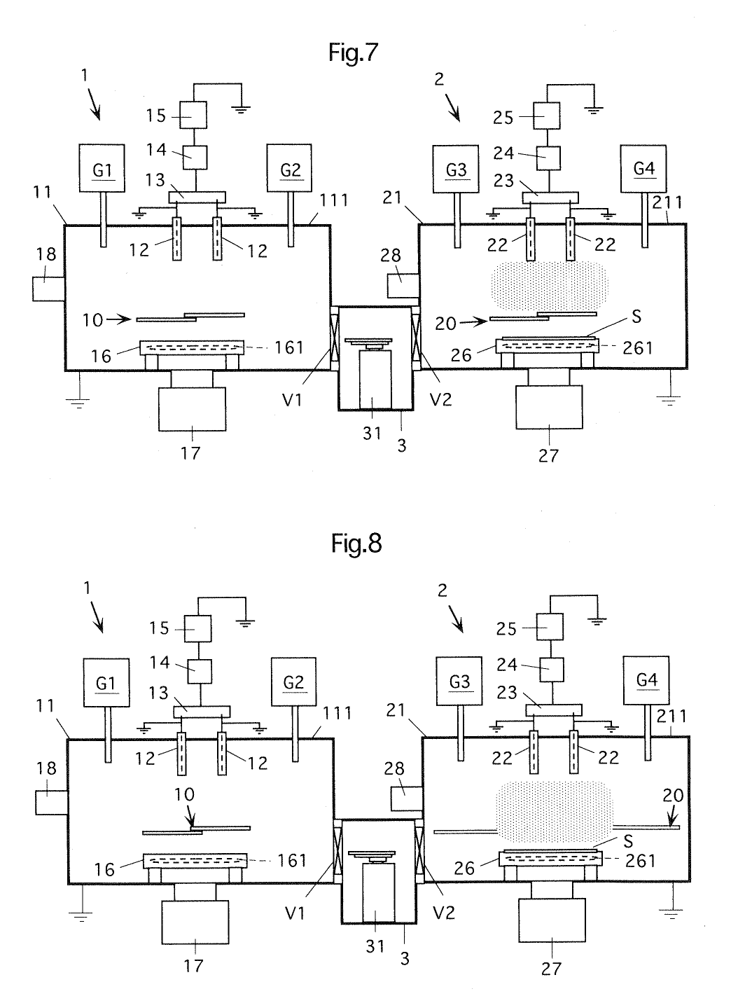

(1) To begin with, the substrate S on which a tunnel silicon oxide film is formed by subjecting the surface of a P-type semiconductor silicon substrate as the to-be-processed substrate S to a thermal oxidation treatment in advance is supported on the substrate holder 16 in the plasma producing chamber 11, and the substrate is heated to 220° C. by the heater 161.
(2) The chamber 11 is evacuated by the exhaust device 17 to reduce the pressure inside the chamber 11 to 2×10⁻⁴ Pa or lower, and then monosilane (SiH₄) gas (0.2 ccm) and hydrogen gas (30 ccm) are supplied into the chamber 11.
(3) While the pressure inside the chamber 11 is maintained to a silicon dot formation pressure of 0.8 Pa (6 mTorr) by supplying the gases and by the operation of the exhaust device 17, high-frequency power of 13.56 MHz and 2000 W is applied to the antennas 12 in a state that the shutter device 10 is closed to cover the substrate S, as shown in FIG. 5, so that formation of inductively coupled plasma from the gases is started.
(4) The state of the plasma is detected by the plasma state detecting device 18. Since the device 18 grasps that the plasma stays in an unstable state for some time from immediately after the ignition of plasma, the shutter controller 41 still keeps the shutter device 10 closed.
(5) As the plasma is stabilized with the lapse of time from the ignition of the plasma, as shown in FIG. 6, the shutter controller 41 opens the shutter device 10 in response to the information from the apparatus 18 that indicates the stabilized state of the plasma to expose the substrate S to the plasma. The temperature of the substrate is raised to 220° C. by this time at the latest. Accordingly, formation of silicon dots on the substrate S is started.
(6) After the time required to form silicon dots having a desired particle diameter elapses, application of electric power to the antennas 12 is stopped, and the gas remaining in the chamber 11 is sufficiently exhausted by the exhaust device 17, thereby completing the formation of single-layer silicon dots.
In such a manner, silicon dots each having an independent particle diameter of about 5 nm when observed by a field emission scanning electron microscope (FE-SEM) can be obtained.
(7) Subsequently, the gate valves V1, V2 are opened. The substrate S on which the silicon dots are formed is transferred from the chamber 11 into the plasma producing chamber 21 of the apparatus 2 for forming insulating film by the transferring robot 31, and is supported on the substrate holder 26. The gate valves V1, V2 are then closed.
(8) The substrate S on the substrate holder 26 is heated to 220° C. by the heater 261.
(9) The chamber 21 is evacuated by the exhaust device 27 to reduce the pressure inside the chamber 21 to 2×10⁻⁴ Pa or lower. A monosilane (SiH₄) gas (8.6 ccm) and oxygen gas (30 ccm) are then supplied into the chamber 21.
(10) While the pressure inside the chamber 21 is maintained to an insulating film formation pressure of 0.8 Pa (6 mTorr) by supplying the gas and by operating the exhaust device 27, high-frequency power of 13.56 MHz and 500 W is applied to the antennas 22 in a state that the shutter device 20 is closed to cover the substrate S, as shown in FIG. 7, so that formation of inductively coupled plasma from the gases is started.
(11) The state of the plasma is grasped by the plasma state detecting device 28. Since the device 28 grasps that the plasma is in an unstable state for some time from immediately after the ignition of the plasma, the shutter controller 42 still keeps the shutter device 20 closed.
(12) As the plasma is stabilized with the lapse of time from the ignition of the plasma, as shown in FIG. 8, the shutter controller 42 opens the shutter device 20 in response to the information from the device 28 that indicates the stabilized state of the plasma to expose the substrate S to the plasma. The temperature of the substrate is raised to 220° C. by this time at the latest. Accordingly, formation of the insulating film (control silicon oxide film) on the substrate S is started.
(13) After the time required to form the control silicon oxide film having a desired thickness elapses, application of electric power to the antennas 22 is stopped, and the gas remaining in the chamber 21 is sufficiently exhausted by the exhaust device 27, thereby completing the formation of the insulating film.
In such a manner, a silicon oxide film having a thickness of about 15 nm when measured by the ellipsometry method can be obtained.

Thus, a substrate shown in, for example, FIG. 16A, which can be utilized for forming a semiconductor device can be obtained.

For example, the substrate used for forming the semiconductor device having two silicon dot layer structure shown in FIG. 16B may be transferred to the plasma producing chamber 11 again after the control silicon oxide film is formed, as described above to form silicon dots, and then the substrate may be transferred to the plasma producing chamber 21 to form a silicon oxide film.
Otherwise, silicon dots and insulating films having a desired laminated layer state can be formed by causing the substrate to reciprocate between the plasma producing chambers 11 and 21.

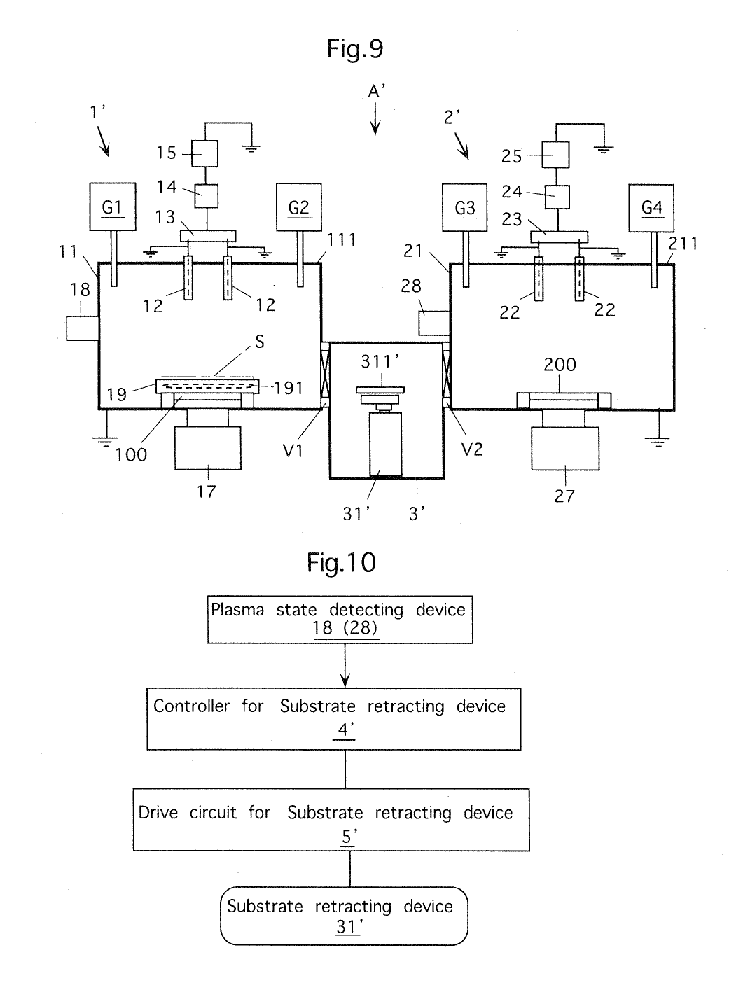

In the apparatus 1 for forming silicon dots and apparatus 2 for forming insulating film described above, the shutter devices 10, 20 are employed for forming the silicon dots and the insulating film after the plasma is stabilized, respectively, but as shown in FIG. 9, a substrate retracting device 31′ may be employed in place of the shutter devices.

FIG. 9 shows an apparatus A′ for forming a substrate with silicon dots and insulating film comprising an apparatus 1′ for forming silicon dots and an apparatus 2′ for forming insulating film.

In the apparatus 1′ for forming silicon dots, a substrate holder supporting base 100 is provided below the antennas 12 in the plasma producing chamber 11, and a substrate holder 19 having a substrate heater 191 can be placed on the supporting base 100. Furthermore, the plasma producing chamber 11 is provided with a substrate retracting device 31′.

In the apparatus 2′ for forming insulating film, a substrate holder supporting base 200 is provided below the antennas 22 in the plasma producing chamber 21, and the substrate holder 19 can be placed on the supporting base 200. Furthermore, the plasma producing chamber 21 is provided with a substrate retracting device 31′, which is also used for the plasma producing chamber 11.

The substrate retracting device 31′ is placed inside a substrate transferring path 3′ which communicates the plasma producing chambers 11 and 21 in an airtight fashion with respect to an ambient air. As in the apparatus A shown in FIG. 1, a gate valve V1 is provided between the path 3′ and the plasma producing chamber 11, and a gate valve V2 is provided between the path 3′ and the plasma producing chamber 21.

The substrate retracting device 31′ has a substrate holder transferring arm 311′ which is capable of elevating, descending, rotating, extending and retracting. The substrate holder 19 with the substrate S supported thereon can be moved between the plasma producing chambers 11 and 21 by the arm to place the substrate holder 19 on the supporting base 100 in the chamber 11 and the supporting base 200 in the chamber 21. Each of the supporting bases 100, 200 is provided with an electricity supply unit (not illustrated) for supplying electric power to a heater 191, and the substrate holder 19 is provided with an electricity receiving unit (not illustrated) which is in contact with the electricity supply unit.

For example, a commercially available substrate transferring robot can be used as such a substrate retracting device 31′.

Although not shown in FIG. 9, the substrate retracting device 31′ is provided with a controller 4′, as shown in FIG. 10. When the information that the plasma formed in the plasma producing chamber 11 (21) is in an unstable state is transmitted from the plasma state detecting device 18 (28) to the controller 4′, the controller 4′ instructs the substrate retracting device drive circuit 5′ to make the device 31′ retract the substrate holder 19 from directly below the antennas 12 (22). In this example, the substrate holder 19 is retracted into the path 3′. When the information that the plasma is stabilized is transmitted from the plasma state detecting device 18 (28) to the control unit 4′, the control unit 4′ instructs the substrate retracting device drive circuit 5′ to make the device 31′ mount the substrate holder 19 on the supporting base 100 (200).

Except for these points, the apparatus A′ shown in FIG. 9 is substantially the same as the apparatus A shown in FIG. 1, and the parts, portions and other components which are substantially the same as those in the apparatus A shown in FIG. 1 are referred to by the same reference numerals or symbols as in the apparatus A.

Example 2 will be described below, in which a substrate with silicon dots and insulating film that can be used for forming semiconductor devices and the like having a MOS capacitor and MOSFET structure shown in FIG. 16A as an example is formed by using the apparatus A′ for forming a substrate with silicon dots and insulating film. In the plasma state detecting devices 18, 28, a fiber optic spectrometer manufactured by Ocean Optics, Inc., USA (model: USB2000) was employed.

### Example 2

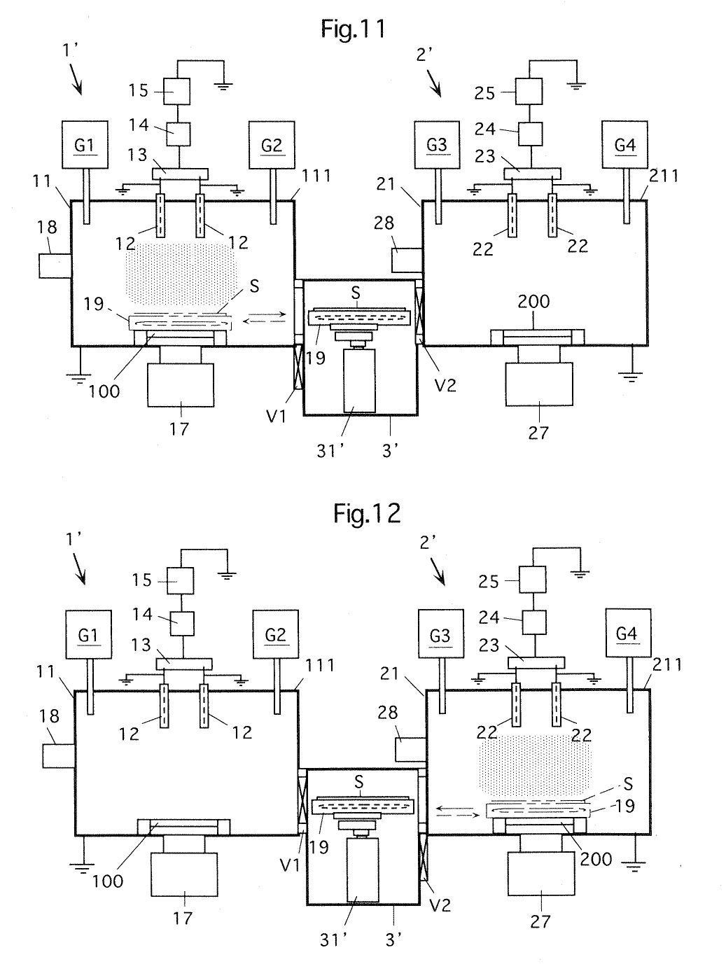

(1) To begin with, the substrate S on which a tunnel silicon oxide film is formed by subjecting the surface of a P-type semiconductor silicon substrate as the to-be-processed substrate S to a thermal oxidation treatment in advance is supported on the substrate holder 19 in the plasma producing chamber 11, and the substrate is heated to 220° C.
(2) The gate valve V1 is opened to evacuate the chamber 11 and path 3′ by the exhaust device 17 and reduce the pressure inside the chamber 11 and path 3′ to 2×10⁻⁴ Pa or lower, and then monosilane (SiH₄) gas (0.2 ccm) and hydrogen gas (30 ccm) are supplied into the chamber 11.
(3) While the pressure inside the chamber 11 is maintained to a silicon dot formation pressure of 0.8 Pa (6 mTorr) by supplying the gases and operating the exhaust device 17, the substrate holder 19, together with the substrate S, is retracted into the path 3′ by the substrate retracting device 31′ as shown in FIG. 11. In such a state that the substrate holder is retracted, high-frequency power of 13.56 MHz and 2000 W is applied to the antennas 12 so that formation of inductively coupled plasma from the gases is started.
(4) The state of the plasma is detected by the plasma state detecting device 18. Since the device 18 detects that the plasma is in an unstable state for some time from immediately after the ignition of plasma, the controller 4′ of the transferring device 31′ is still keeping the substrate holder 19 retracted into the path 3′.
(5) As the plasma is stabilized with the lapse of time from the ignition of the plasma, the controller 4′ has the holder 19 mounted on the supporting base 100 in the plasma producing chamber 11 by the plasma transferring device 31′ in response to the information from the apparatus 18 that indicates the stabilized state of plasma, and closes the gate valve V1. While the substrate S is retracted, it is kept supported on the holder 19 having a large heat capacity, and therefore the temperature of the substrate is rapidly raised back to 220° C. Thus, formation of silicon dots on the substrate S is started.
(6) After the time required to form silicon dots having a desired particle diameter elapses, application of electric power to the antennas 12 is stopped, and the gas remaining in the chamber 11 is sufficiently exhausted by the exhaust device 17, thereby completing the formation of single-layer silicon dots.
In such a manner, silicon dots each having an independent particle diameter of about 5 nm, when observed by a field emission scanning electron microscope (FE-SEM), can be obtained.
(7) Subsequently, the gate valves V1, V2 are opened, and the substrate holder 19 which still supports the substrate S having silicon dots formed thereon is transferred by the transferring device 31′ from the chamber 11 onto the supporting base 200 in the plasma producing chamber 21 of the apparatus 2′ for forming insulating film. The gate valve V1 is closed, and the substrate is heated to 220° C.
(8) The gate valve V2 is opened to evacuate the chamber 21 and path 3′ by the exhaust device 27. The pressure inside the chamber 21 and path 3′ is reduced to 2×10⁻⁴ Pa or lower, and then monosilane (SiH₄) gas (8.6 ccm) and oxygen gas (30 ccm) are supplied into the chamber 21.
(9) While the pressure inside the chamber 21 is maintained to an insulating film formation pressure of 0.8 Pa (6 mTorr) by supplying the gases and operating the exhaust device 27, the substrate holder 19, together with the substrate S, is retracted into the path 3′ by the substrate retracting device 31′ in a manner similar to that shown in FIG. 11 (as shown in FIG. 12), and high-frequency power of 13.56 MHz and 500 W is applied to the antennas 22 in such a state that the substrate holder is retracted to start formation of inductively coupled plasma from the gases.
(10) The state of the plasma is detected by the plasma state detecting device 28. Since the device 28 detects that the plasma is in an unstable state for some time from immediately after the ignition of the plasma, the controller 4′ of the transferring device 31′ still keeps the substrate holder 19 retracted into the path 3′.
(11) As the plasma is stabilized with the lapse of time from the ignition of the plasma, the controller 4′ has the holder 19 mounted on the supporting base 200 in the plasma producing chamber 21 by the transferring device 31′ in response to the information from the device 28 that indicates the stabilized state of the plasma, and closes the gate valve V2. While the substrate S is retracted, it is kept supported on the holder 19 having a large heat capacity, and therefore the temperature of the substrate is rapidly raised back to 220° C. Thus, formation of an insulating film (control silicon oxide film) on the substrate S is started.
(12) After the time required to form the control silicon oxide film having a desired thickness elapses, application of electric power to the antennas 22 is stopped, and the gas remaining in the chamber 21 is sufficiently exhausted by the exhaust device 27, thereby completing the formation of the insulating film.
In such a manner, a silicon oxide film having a thickness of about 15 nm when measured by the ellipsometry method can be obtained.

In such a manner, for example, the substrate which can be utilized for forming a semiconductor device shown in FIG. 16A can be obtained.

For example, the substrate used for forming the semiconductor device having two silicon dot layer structure as shown in FIG. 16B may be transferred to the plasma producing chamber 11 again after the control silicon oxide film is formed to form silicon dots, as described above, and then the substrate may be transferred to the plasma producing chamber 21 to form a silicon oxide film.

Otherwise, the silicon dots and insulating films having a desired laminated layer state can be formed by causing the substrate to reciprocate between the plasma producing chambers 11 and 21.

In the apparatus 1 (1′) for forming silicon dots described above and formation of silicon dots using the same, silicon dots can be formed at a relatively low temperature while suppressing defects and clustering of silicon dots, which may be generated at a high temperature, by employing the inductively coupled plasma CVD method of internal antenna type, and also the silicon dots can be formed in high-density plasma formed by employing the internal antennas (first antennas 12) with reduced inductance placed in the first plasma producing chamber 11, while suppressing damages to the substrate and silicon dots formed thereon.

Moreover, in, forming the silicon dots, the substrate S is placed in such a state that it is not exposed to unstable plasma by covering the substrate with the shutter device 10 to shield the substrate from plasma, or retracting the substrate from plasma by the substrate retracting device 31′, while the plasma produced in the plasma producing chamber 11 is in an unstable state, and the shutter device 10 is opened to expose the substrate S to stabilized plasma, or by placing the substrate S in a position where it is exposed to stabilized plasma by the substrate retracting device 31′, when the plasma is stabilized to start formation of silicon dots on the substrate S. Therefore, silicon dots can be formed with high controllability of the particle diameter of the silicon dots and high reproducibility between substrates.

According to the apparatuses A, A′ for forming substrate with silicon dots and insulating film described above and the formation of the substrate with silicon dots and insulating film using the same, silicon dots can be formed at a relatively low temperature while suppressing the occurrence of defects and clustering of silicon dots which may occur at a high temperature, suppressing damages caused by plasma, with high controllability of the particle diameter of the silicon dots and high reproducibility of substrates.

An insulating film can be also formed at a relatively low temperature by the internal antenna type inductively coupled plasma CVD method, and the insulating film can be formed in high-density plasma formed by employing an internal antenna (second antennas 22) with reduced inductance placed in the second plasma producing chamber 21, while suppressing damages to the insulating film caused by the plasma or damages to silicon dots, which are formed earlier.

Moreover, in forming the insulating film, while the plasma produced in the second plasma producing chamber 21 is in an unstable state, the substrate S is shielded from the plasma by the shutter device 20, or the substrate S is retracted from the plasma by the substrate retracting device 31′, whereby the substrate is placed in such a state that it is not exposed to unstable plasma, and when the plasma is stabilized, the shutter device 20 is opened to expose the substrate S to the stabilized plasma, or the substrate S is placed in a position where it is exposed to the stabilized plasma by the substrate retracting device 31′ to start the formation of insulating film on the substrate S. Therefore, an insulating film can be formed with high controllability of the thickness and high reproducibility between substrates.

Furthermore, when the substrate S is transferred from the plasma producing chamber 11 to the plasma producing chamber 21 or the other way round, the transferring is carried out through the substrate transferring paths 3, 3′ which are shut off in an airtight fashion with respect to an ambient air. Therefore, the formed silicon dots and the insulating film are prevented from deposition or contamination of undesired impurities in the atmosphere, and proportionally good silicon dots and insulating film can be obtained.

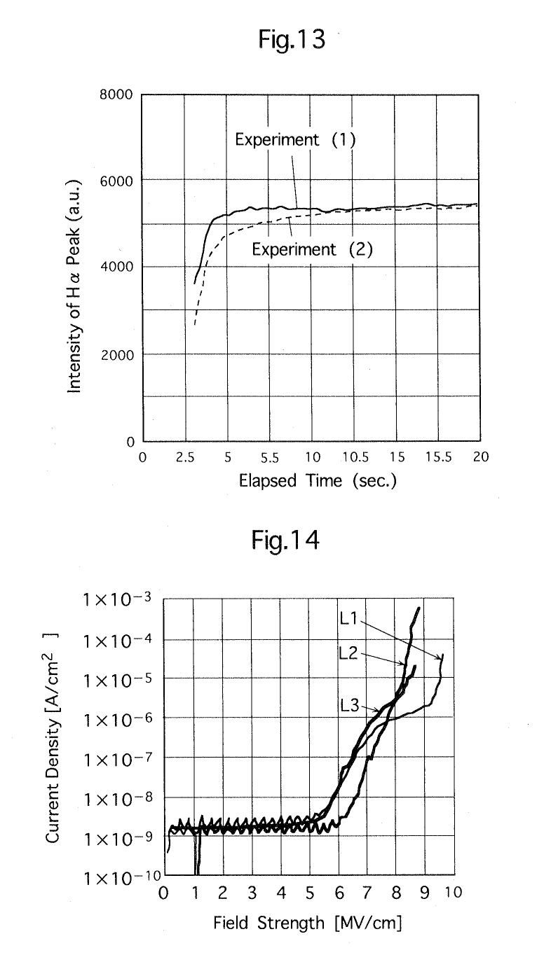

For reference, the results of the following measurement are shown in FIG. 13: in the apparatus 2 for forming insulating film shown in FIG. 1, monosilane gas (8.6 sccm) and oxygen gas (30 sccm) were supplied into the plasma producing chamber 21. While the pressure inside the chamber was maintained to 0.8 Pa (6 mTorr), electric power of 13.56 MHz and 500 W was applied to the antennas 22 to produce inductively coupled plasma from the gases. This production of plasma was conducted twice. The spectral intensity of hydrogen radicals (Hα) serving as an index of the stability or instability in plasma was measured for each production by the fiber optical spectroscope (model: USB2000). In FIG. 13, the horizontal axis represents the lapse of time from the ignition of plasma, while the vertical axis represents the spectral intensity of hydrogen radicals (Hα).

As can be seen from FIG. 13, even when the same apparatus is used and the same plasma producing conditions are employed to produce plasma, the time required for the spectral intensity of the hydrogen radicals (Hα) to be constant, that is, the time required for plasma to be stabilized, varies each time plasma is ignited.

Hence, the above apparatus 1 for forming silicon dots and apparatus 2 for forming insulating film are so designed that the substrate S is shielded from plasma by using the shutter devices 10, 20 while the plasma is unstable, and the substrate S is exposed to stabilized plasma when the plasma is stabilized so that formation of silicon dots and insulating film is started.

For reference purpose, the results of measurement of current-voltage characteristics of each of the silicon oxide films produced by employing an N-type semiconductor silicon substrate as a to-be-processed substrate, described below, are shown in FIG. 14:

(1) A silicon oxide film formed on the substrate in the apparatus 2 for forming insulating film shown in FIG. 1 by using monosilane gas (8.6 ccm) and oxygen gas (30 ccm), maintaining the deposition pressure to 0.8 Pa (6 mTorr) and the substrate temperature to 220° C., and applying high-frequency power of 13.56 MHz and 500 W to the antennas 22,
(2) A silicon oxide film formed on the substrate in a film forming apparatus employing the capacitive coupling plasma CVD and using parallel plate electrodes, which are not illustrated, by using monosilane gas (300 ccm) and oxygen gas (1000 ccm), maintaining the deposition pressure to 2.7 Pa (20 mTorr) and the substrate temperature to 400° C., and applying high-frequency power of 13.56 MHz, 10000 W, and
(3) A silicon oxide film formed on an identical substrate by the thermal CVD method.

In FIG. 14, a line L1 represents a film formed in capacitive coupling plasma; a line L2 represents a film formed by heat oxidation: and a line L3 represents a film formed in the apparatus 2 for forming insulating film.

As can be seen from FIG. 14, silicon oxide films which exhibit the qualities (leakage current, withstand voltage) similar to those of the silicon oxide films formed by the known capacitive coupling plasma CVD and by the thermal oxidation treatment, respectively, can be also obtained even at a low temperature in the present invention.

Silicon dots were formed at substrate temperatures of 250° C., 300° C. and 450° C., respectively, by using the apparatus 1 for forming silicon dots of FIG. 1, employing a P-type semiconductor silicon substrate as the to-be-processed substrate, using monosilane gas (0.2 ccm) and hydrogen gas (30 ccm), maintaining the silicon dot formation pressure to 0.8 Pa (6 mTorr), and using the power input to the antennas 12 of 13.56 MHz, 2000 W, and the particle diameter of the silicon dots at each substrate temperature was measured with a field emission scanning electron microscope (FE-SEM) to determine the variation of the particle diameter. The results are shown below for reference purpose.

Substrate temperature: 430° C., 300° C., 250° C.
Particle diameter

distribution (nm): 7.2±0.8, 7.7±0.7, 6.9±0.5

The greater the particle diameter distribution, the higher the temperature, assumedly because the silicon dots tend to gather. These results show that the lower the temperature for forming the silicon dots, the less the variation of the particle diameter of the silicon dots. Therefore, it is understood that the lower the temperature for forming the silicon dots and the following processes, the more preferable.

Silicon oxide films were formed three times each in a state that the substrate is exposed to plasma from the ignition of plasma by employing an N-type semiconductor silicon substrate as a to-be-processed substrate, using monosilane gas (0.2 ccm) and hydrogen gas (30 ccm), maintaining the silicon dot formation pressure to 0.8 Pa (6 mTorr), using the power input to the antennas 12 of 13.56 MHz, 500 W, maintaining the substrate temperature to 220° C., and

(1) using the shutter device 20 in the apparatus 2 for forming insulating film of FIG. 1, as described above,
(2) using the substrate retracting device 31′ in the apparatus 2′ for forming insulating film of FIG. 9, as described above, or
(3) not using the shutter device 20 in the apparatus 2 for forming insulating film of FIG. 1.

The variation in deposition rate of these silicon oxide films were determined by measuring their film thickness by the ellipsometry method. The results are shown below.

Method for forming films: above (1), above (2), above (3) SiO₂ deposition

Rate (Å/sec.): 6.7±0.5, 6.8±1.1, 8.1±1.9

It is understood from these results that the reproducibility of the film thickness (the smallness of variation) is better in the method in which the shutter device 20 and the substrate retracting device 31′ are used and the substrate is not exposed to plasma in an unstable state and the films are formed after the plasma is stabilized than in the case where the substrate is exposed to plasma from the ignition of plasma to form films without using the shutter device 20.

In forming the silicon dots and insulating film described above, the silicon substrate having a heat-resistant oxidized film was employed as the to-be-processed substrate, but, for example, the silicon dots and insulating film can be also formed on a substrate comprising a material having a low heat-resistant temperature such as non-alkali glass substrate, and an insulating film and silicon dots, if necessary, can be also formed on such a substrate, which offers a wide range of selection of substrate materials.

In forming the silicon dots of Examples 1 and 2 described above, a silane-based gas (monosilane gas) and hydrogen gas are supplied into the plasma producing chamber 11, and inductively coupled plasma is produced from the gases to form silicon dots in plasma. However, silicon dots can be also formed by, for example, the following procedure.

(a) Another Example of Formation of Silicon Dots

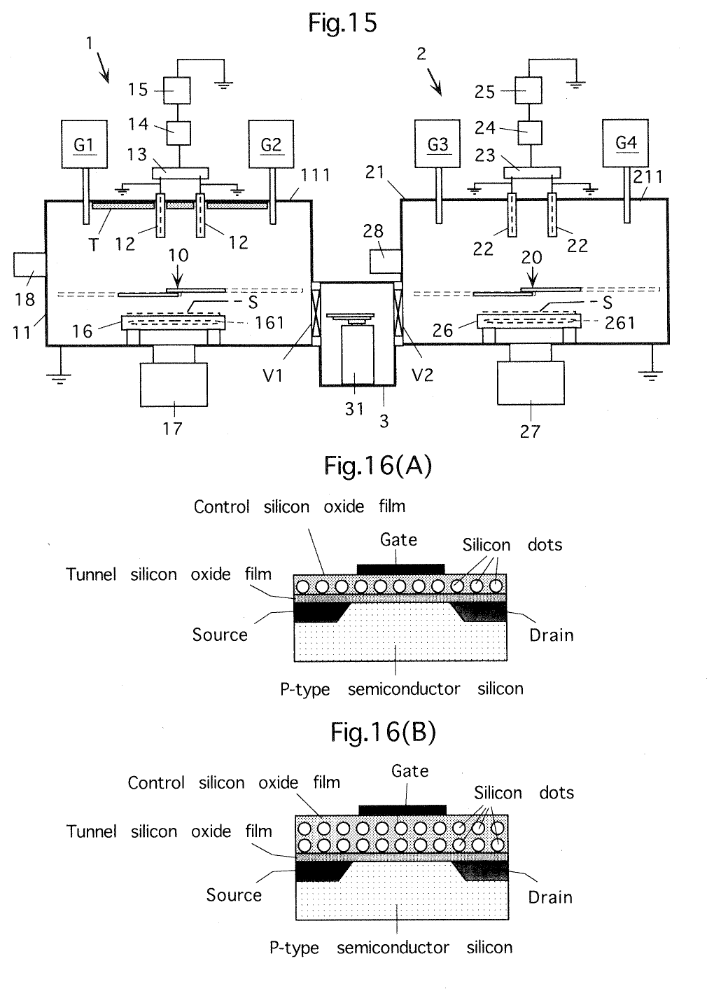

As shown in FIG. 15, in the apparatus 1 for forming silicon dots of FIG. 1, silicon dots are formed on the substrate S by affixing a silicon sputter target T on, for example, the inner surface of the top wall 111 in the plasma producing chamber 11 in advance, in forming the silicon dots, supplying hydrogen gas into the chamber 11 to produce inductively coupled plasma from the gas, placing the substrate S in such a state that it is not exposed to unstable plasma by the shutter device 10 while the plasma is in an unstable state, opening the shutter device 10 to expose the substrate S to stabilized plasma when the plasma is stabilized, and conducting chemical sputtering of the silicon sputter target T by the stabilized plasma. Commercially available silicon wafers and substrates produced by forming a silicon film on a target substrate, among others, can be employed as the silicon sputter target.

Examples of conditions in this case will be described below.

Silicon sputter target: Single-crystalline silicon sputter target
High-frequency power applied to antennas 12: 60 MHz, 4 kW
Silicon dot formation target substrate: Silicon wafer covered with heat-oxidized film (SiO₂)
Substrate temperature: 400° C.
Internal pressure of chamber: 0.6 Pa
Hydrogen gas: 100 sccm

Silicon dots having a uniform particle diameter of 10 nm or smaller could be formed under these conditions.

(b) Still Another Example of Formation of Silicon Dots

Silicon dots can be formed on the substrate S by the procedure described below, instead of employing of the silicon sputter target shown in FIG. 15: gases for forming silicon film (monosilane gas and hydrogen gas when the apparatus of FIG. 1 is utilized) are supplied to produce plasma from the gases by applying high-frequency power to the first antennas 12 prior to silicon dot formation; a silicon film is formed in the plasma on a target member (the inner wall of the chamber 11 and (or) the target substrate placed in the chamber 11 in advance) in the plasma chamber 11; in forming the silicon dots, hydrogen gas is supplied into the chamber 11 to produce inductively coupled plasma from the gas; while the plasma is in an unstable state, the shutter device 10 is closed to place the substrate S in such a state that it is not exposed to unstable plasma; when the plasma is stabilized, the shutter device 10 is opened to expose the substrate S to the stabilized plasma; and chemical sputtering of the silicon film is carried out by the stabilized plasma.

Examples of silicon film formation conditions and silicon dot formation conditions in this case will be described below.

### <Conditions for Forming Silicon Film on Inner Wall of Chamber>

High-frequency power applied to antennas 12:
13.56 MHz, 10 kW

Temperature of inner wall of chamber 11:

80° C. (heated by heater installed inside chamber)

Internal pressure of chamber: 0.67 Pa

Monosilane gas: 100 sccm

Hydrogen gas: 150 sccm

### <Conditions for Forming Silicon Dots>

High-frequency power applied to antennas 12:
13.56 MHz, 5 kW

Temperature of inner wall of chamber 11:

80° C. (heated by heater installed inside chamber)

Substrate on which silicon dots are to be formed:

Silicon wafer covered with heat-oxidized film (SiO₂)

Substrate temperature: 430° C.

Internal pressure of chamber: 0.67 Pa

Hydrogen gas: 150 sccm

Under these conditions, silicon dots having an average particle diameter of 10 nm or lower could be formed.

It is desirable that the surfaces of the silicon dots are terminally treated with oxygen, nitrogen or other elements as already mentioned.

To this end, in the silicon dot formation according to the present invention, whether the insulating film is formed or not formed after the silicon dots are formed, the surfaces of the silicon dots may be subjected to a terminating treatment in plasma for terminating treatment produced by applying high-frequency power to at least one gas for terminating treatment selected from an oxygen-containing gas and a nitrogen-containing gas.

Such a terminating treatment may be also conducted in the following manner as long as it poses no problem: after the silicon dots are formed, the gas for terminating treatment is introduced into the same plasma producing chamber 11, and high-frequency power is applied to the gas from the antennas 12 to generate inductively coupled plasma for terminating treatment so that the surfaces of the silicon dots are subjected to a terminating treatment in the plasma.

Moreover, a terminally treating chamber which is independent of the apparatus 1 (1′) for forming silicon dots may be prepared, in which a terminating treatment step may be carried out in capacitive coupling plasma or inductively coupled plasma of the gas for terminating treatment.

After the silicon dots are formed in the plasma producing chamber 11, the substrate on which the silicon dots are formed may be loaded into the terminally treating chamber which is in communication with the plasma producing chamber 11 (directly or indirectly via a transference chamber having a goods transferring robot, etc.), and a terminating treatment may be conducted in the terminally treating chamber.

When such a terminally treating chamber is provided, a substrate transferring path which connects the terminally treating chamber and the plasma producing chamber 21 in an airtight fashion with respect to an ambient air may be provided, and when an insulating film is formed on the silicon dots after the terminating treatment, the substrate may be loaded into the second plasma producing chamber 21 from the path to form the insulating film.

In both cases, the antenna which applies high-frequency power to the gas for terminating treatment in the terminating treatment in the terminally treating chamber may be either that which produces inductively coupled plasma or that which produces capacitive coupling plasma.

An oxygen-containing gas or (and) a nitrogen-containing gas is (are) used as the gas for terminating treatment, as mentioned above. Examples of the oxygen-containing gas include oxygen gas and nitrogen oxide (NO₂) gas. Examples of the nitrogen-containing gas include nitrogen gas and ammonia (NH₃) gas.

Experimental Examples 1, 2, which were prepared by subjecting the silicon dots formed in the same step as the silicon dot formation step of Example 1 to a terminating treatment, are shown below. The terminating treatment was carried out in the plasma producing chamber 11. Although not illustrated, an oxygen gas supply device for supplying oxygen gas into the chamber 11 was prepared when oxygen terminating treatment was carried out, while a nitrogen gas supply device for supplying nitrogen gas into the chamber 11 was prepared when nitrogen terminating treatment was carried out.

### Experimental Example 1

### Formation of Silicon Dots Subjected to Oxygen Terminating Treatment

Substrate temperature at which silicon dots were formed: 400° C.

Amount of oxygen gas supplied: 100 sccm

High-frequency power to antennas 12: 13.56 MHz, 1 kW

Terminating treatment pressure: 0.67 Pa

Process time: 1 minute

### Experimental Example 2

### Formation of Silicon Dots Subjected to Nitrogen Terminating Treatment

Substrate temperature at which silicon dots were formed: 400° C.

Amount of nitrogen gas supplied: 200 sccm

High-frequency power: 13.56 MHz 1 kW

Terminating treatment pressure: 0.67 Pa

Process time: 5 minutes

The silicon dots which were terminally treated with oxygen or nitrogen in such a manner can improve the characteristics of electronic devices utilizing the same. For example, when the silicon dots are utilized for a light-emitting element, they can improve its luminance.

### INDUSTRIAL APPLICABILITY

The present invention can be used for forming silicon dots of minute particle diameters that are used as electronic device materials, light emission materials and others, and for forming a substrate with silicon dots and an insulating film, in which silicon dots and an insulating film are formed on one another which can be used for semiconductor devices such as MOS capacitors and MOS-FETs.

1. A method for forming silicon dots comprising
applying high-frequency power to a first antenna with low inductance placed in a first plasma producing chamber to generate inductively coupled plasma from a gas for forming silicon dots supplied into the chamber, and forming silicon dots on a substrate disposed inside the chamber in the inductively coupled plasma, wherein in forming the silicon dots; while the plasma generated in the first plasma producing chamber is in an unstable state, the substrate is placed in such a state that the substrate is not exposed to the unstable plasma; and when the plasma is stabilized, the substrate is exposed to the stabilized plasma to start formation of silicon dots on the substrate.

2. The method for forming silicon dots according to claim 1, wherein an openable and closable shutter device for shielding the substrate disposed in the first plasma producing chamber from the plasma produced in the chamber is provided; in forming the silicon dots, the substrate is placed in such a state that the substrate is shielded from the plasma by the shutter device to avoid exposure to unstable plasma until the plasma in the first plasma producing chamber is stabilized; and when the plasma is stabilized, the shutter device is opened to start formation of silicon dots on the substrate in the stabilized plasma.

3. The method for forming silicon dots according to claim 1, wherein a substrate retracting device for retracting the substrate disposed in the first plasma producing chamber from the plasma produced in the chamber is provided; in forming the silicon dots, the substrate is retracted from the plasma to avoid exposure to the unstable plasma by the substrate retracting device until the plasma in the first plasma producing chamber is stabilized; and when the plasma is stabilized, the substrate is disposed in a position where the substrate is exposed to the stabilized plasma by the substrate retracting device to start formation of silicon dots on the substrate.

4. The method for forming silicon dots according to claim 1, 2 or 3, wherein the unstable state and stable state of the plasma produced in the first plasma producing chamber are detected by a plasma state detecting device provided for the first plasma producing chamber.

5. The method for forming silicon dots according to claim 1, 2 or 3, wherein in forming the silicon dots, a silane-based gas and hydrogen gas are supplied into the first plasma producing chamber as the gases for forming silicon dots; the inductively coupled plasma is produced from these gases; while the plasma is in an unstable state, the substrate is placed in such a state that the substrate is not exposed to the unstable plasma; and when the plasma is stabilized, the substrate is exposed to the stabilized plasma to start forming silicon dots on the substrate.

6. The method for forming silicon dots according to claim 1, 2 or 3, wherein a silicon sputter target is placed in the first plasma producing chamber in advance; in forming the silicon dots, a gas for sputtering is supplied into the first plasma producing chamber as the gas for forming silicon dots to generate inductively coupled plasma from the gas for sputtering; while the plasma is unstable, the substrate is placed in a state that the substrate is not exposed to the unstable plasma; when the plasma is stabilized, the substrate is exposed to the stabilized plasma to start formation of silicon dots on the substrate by chemical sputtering of the silicon sputter target with the stabilized plasma.

7. The method for forming silicon dots according to claim 1, 2 or 3, wherein prior to the formation of the silicon dots, a gas for forming silicon film is supplied into the first plasma producing chamber to produce plasma from the gas by applying high-frequency power to the first antenna; a silicon film is formed on a member on which a silicon film is to be formed in the first plasma producing chamber in the plasma; in forming the silicon dots, a gas for sputtering is supplied into the first plasma producing chamber as the gas for forming silicon dots to produce the inductively coupled plasma from the gas for sputtering; while the plasma is unstable, the substrate is placed in a state that the substrate is not exposed to the unstable plasma; and when the plasma is stabilized, the substrate is exposed to the stabilized plasma to start formation of silicon dots on the substrate by chemical sputtering of the silicon film with the stabilized plasma.

8. The method for forming silicon dots according to claim 1, 2 or 3, wherein after the formation of the silicon dots, the surfaces of the silicon dots are terminally treated in plasma for terminating treatment produced by applying high-frequency power to at least one gas for terminating treatment selected from an oxygen-containing gas and a nitrogen-containing gas.

9. The method for forming silicon dots according to claim 8, wherein after the silicon dots are formed in the first plasma producing chamber, the substrate on which the silicon dots are formed is loaded into a terminally treating chamber which is in communication with the first plasma producing chamber; and the terminating treatment is carried out in the terminally treating chamber.

10. A method for forming a substrate with silicon dots and an insulating film,
the silicon dots being formed at least once and the insulating film being formed at least once on a substrate;
the silicon dots being formed by the method for forming silicon dots according to claim 1, 2 or 3;
the insulating film being formed by employing a method in which high-frequency power is applied to a second antenna with reduced inductance placed in a second plasma producing chamber to generate inductively coupled plasma from a gas for forming an insulating film supplied into the second chamber, and an insulating film is formed on the substrate disposed in the second chamber in the inductively coupled plasma; in forming an insulating film according to the method for forming an insulating film, the substrate being placed in a state that the substrate is not exposed to unstable plasma while the plasma generated in the second plasma producing chamber is unstable; the substrate being exposed to stabilized plasma when the plasma is stabilized to start forming an insulating film on the substrate;
when the insulating film is formed after the silicon dots are formed, the substrate being transferred from a chamber where the substrate is present to the second plasma producing chamber through a substrate transferring path which communicates the two chambers in an airtight fashion with respect to an ambient air; and when the silicon dots are formed after the insulating film is formed, the substrate being transferred from the second plasma producing chamber to the first plasma producing chamber through a substrate transferring path which communicates the two chambers in an airtight fashion with respect to an ambient air.

11. The method for forming a substrate with silicon dots and insulating film according to claim 10, wherein an openable and closable shutter device for shielding the substrate disposed in the second plasma producing chamber from plasma produced in the second plasma producing chamber is provided; in forming an insulating film, the substrate is placed in such a state that the substrate is shielded from the plasma by the shutter device to avoid exposure to unstable plasma until the plasma in the second plasma producing chamber is stabilized; and when the plasma is stabilized, the shutter device is opened to start formation of an insulating film on the substrate in the stabilized plasma.

12. The method for forming a substrate with silicon dots and insulating film according to claim 10, wherein a substrate retracting device which retracts the substrate disposed in the second plasma producing chamber from plasma produced in the second plasma producing chamber is provided; in forming an insulating film, the substrate is retracted by the substrate retracting device from the plasma to avoid exposure to unstable plasma until the plasma in the second plasma producing chamber is stabilized; and when the plasma is stabilized, the substrate is disposed in a position where the substrate is exposed to the stabilize plasma by the substrate retracting device to start formation of an insulating film on the substrate.

13. The method for forming a substrate with silicon dots and insulating film according to claim 10, wherein the substrate is supported by a substrate holder having a substrate heater, in forming the insulating film after the silicon dots are formed, when the substrate is transferred from the chamber where the substrate is present to the second plasma producing chamber side through the substrate transportation path, and in forming the silicon dots after the insulating film is formed, when the substrate is transferred from the second plasma producing chamber to the first plasma producing chamber side through the substrate transferring path, the substrate is transferred together with the substrate holder.

14. The method for forming a substrate with silicon dots and insulating film according to claim 10, wherein the unstable state and the stable state of the plasma produced in the second plasma producing chamber are detected by a plasma state detecting device provided for the second plasma producing chamber.

15. The method for forming substrate with silicon dots and insulating film according to claim 10, wherein in the forming of an insulating film, a silane-based gas and oxygen gas are introduced into the second plasma producing chamber as the gases for forming an insulating film; the inductively coupled plasma is produced from these gases; while the plasma is unstable, the substrate is placed in a state that the substrate is not exposed to the unstable plasma; and when the plasma is stabilized, the substrate is exposed to the stabilized plasma to start formation of a silicon oxide insulating film on the substrate.

16. An apparatus for forming silicon dots comprising:
a first plasma producing chamber,
a first gas supply device for supplying a gas for forming silicon dots into the first plasma producing chamber;
a first antenna with reduced inductance placed in the first plasma producing chamber;
a first high-frequency power applying device for generating inductively coupled plasma from the gas supplied from the first gas supply device by applying high-frequency power to the first antenna;
a first plasma state managing device which, in forming the silicon dots, places a substrate on which silicon dots are to be formed disposed in the first plasma producing chamber in a state that the substrate is not exposed to unstable plasma while the plasma in the first plasma producing chamber is unstable and exposes the substrate to stabilized plasma when the plasma is stabilized;
a first plasma state detecting device which detects the state of the plasma in the first plasma producing chamber; and
a first controller for controlling the first plasma state managing device in such a manner that the substrate is placed in a state that the substrate is not exposed to unstable plasma when the state of the plasma generated in the first plasma producing chamber detected by the first plasma state detecting device is =stable, and the substrate is exposed to stabilized plasma when the plasma is stabilized.

17. The apparatus for forming silicon dots according to claim 16, wherein the first plasma state managing device is an openable and closable shutter device which shields the substrate disposed in the first plasma producing chamber from the plasma produced in the plasma producing chamber or exposes to the plasma, and the first controller controls the shutter device in such a manner that in forming the silicon dots on the substrate, the substrate is shielded from the plasma so that the substrate is placed in a state that the substrate is not exposed to unstable plasma by the shutter device until the plasma in the first plasma producing chamber is stabilized, and the shutter device is opened to start forming silicon dots on the substrate in the stabilized plasma when the plasma is stabilized.

18. The apparatus for forming silicon dots according to claim 16, wherein the first plasma state managing device is a substrate retracting device which retracts the substrate disposed in the first plasma producing chamber from the plasma produced in the first plasma producing chamber or transfers the substrate from a retracted position to a position where the substrate is exposed to the plasma, and the first controller controls the substrate retracting device in a manner that in forming the silicon dots on the substrate, the substrate retracting device retracts the substrate from the plasma to place the substrate in such a state that the substrate is not exposed to unstable plasma until the plasma in the first plasma producing chamber is stabilized, and the substrate retracting device places the substrate in a position where the substrate is exposed to stabilized plasma when the plasma is stabilized.

19. The apparatus for forming silicon dots according to any one of claims 16 to 18, wherein the first gas supply device supplies a silane-based gas and hydrogen gas as gases for forming silicon dots into the first plasma producing chamber.

20. The apparatus for forming silicon dots according to any one of claims 16 to 18, wherein a silicon sputter target is placed in the first plasma producing chamber, and the first gas supply device supplies a gas for sputtering which is used for chemical sputtering of the silicon sputter target by being changed into plasma as the gas for forming silicon dots into the first plasma producing chamber.

21. The apparatus for forming silicon dots according to any one of claims 16 to 18, wherein prior to the formation of the silicon clots, a device for supplying gas for forming silicon film which supplies, into the first plasma producing chamber, the gas for forming silicon film which forms a silicon film by being changed into plasma on a member on which a silicon film is to be formed in the first plasma producing chamber is provided, and the first gas supply device supplies the gas for sputtering which is used for chemical sputtering of the silicon film by being changed into plasma as the gas for forming silicon dots into the first plasma producing chamber.

22. The apparatus for forming silicon dots according to any one of claims 16 to 18, which further comprises a device for supplying gas for terminating treatment which supplies at least one gas for terminating treatment selected from an oxygen-containing gas and a nitrogen-containing gas into the first plasma producing chamber after the silicon dots are formed.

23. The apparatus for forming silicon dots according to any one of claims 16 to 18, which further comprises a terminally treating chamber which is in communication with the first plasma producing chamber in such a manner that the substrate on which silicon dots are formed in the first plasma producing chamber can be loaded thereinto, and subjects the silicon dots on the substrate transferred from the first plasma producing chamber to a terminating treatment in plasma for terminating treatment produced by applying high-frequency power to at least one gas for terminating treatment selected from an oxygen-containing gas and a nitrogen-containing gas.

24. An apparatus for forming a substrate with silicon dots and insulating film comprising the apparatus for forming silicon dots according to any one of claims 16 to 18 and an apparatus for forming insulating film, the apparatus for forming insulating film comprising:
a second plasma producing chamber;
a second gas supply device which supplies a gas for forming an insulating film into the second plasma producing chamber;
a second antenna with reduced inductance placed in the second plasma producing chamber;
a second high-frequency power applying device for applying high-frequency power to the second antenna to produce inductively coupled plasma from the gas supplied from the second gas supply device into the second plasma producing chamber;
a second plasma state managing device which, in forming the insulating film, places an insulating film formation target substrate disposed in the second plasma producing chamber in a state that the substrate is not exposed to unstable plasma while the plasma in the second plasma producing chamber is unstable and exposes the substrate to stabilized plasma when the plasma is stabilized;
a second plasma state detecting device for detecting the state of the plasma produced in the second plasma producing chamber, and
a second controller for controlling the second plasma state managing device in such a manner that the substrate is placed in a state that the substrate is not exposed to unstable plasma when the state of the plasma generated in the second plasma producing chamber detected by the second plasma state detecting device is unstable, and the substrate is exposed to stabilized plasma when the plasma is stabilized, and
the first plasma producing chamber and the second plasma producing chamber being in communication via a substrate transferring path for transferring the substrate between the two chambers in an airtight fashion with respect to an ambient air.

25. The apparatus for forming a substrate with silicon dots and insulating film according to claim 24, wherein the second plasma state managing device is an operable and closable shutter device which shields the substrate disposed in the second plasma producing chamber from the plasma produced in the plasma producing chamber or exposes the same to the plasma, and the second controller controls the shutter device in such a manner that in forming the insulating film on the substrate, the substrate is shielded from the plasma to avoid exposure of the substrate to unstable plasma by the shutter device until the plasma in the second plasma producing chamber is stabilized, and the shutter device is opened to start formation of an insulating film in the stabilized plasma when the plasma is stabilized.

26. The apparatus for forming a substrate with silicon dots and insulating film according to claim 24, wherein the second plasma state managing device is a substrate retracting device which retracts the substrate disposed in the second plasma producing chamber from the plasma produced in the second plasma producing chamber or transfers the substrate from a retracted position to a position where the substrate is exposed to the plasma, and the second controller controls the substrate retracting device in such a manner that in forming the insulating film on the substrate, the substrate retracting device retracts the substrate from the plasma to avoid exposure of the substrate to unstable plasma until the plasma in the second plasma producing chamber is stabilized, and the substrate retracting device places the substrate in a position where the substrate is exposed to stabilized plasma when the plasma is stabilized.

27. The apparatus for forming a substrate with silicon dots and insulating film according to claim 24, wherein a substrate holder having a substrate heater and a device for transferring the substrate holder are provided, and in forming the insulating film after the silicon dots are formed, when the substrate is transferred from the first plasma producing chamber to the second plasma producing chamber side through the substrate transportation path, and in forming the silicon dots after the insulating film is formed, when the substrate is transferred from the second plasma producing chamber to the first plasma producing chamber side through the substrate transferring path, the substrate holder transferring device, transfers the substrate together with the substrate holder.

28. The apparatus for forming a substrate with silicon dots and insulating film according to claim 24, wherein the second gas supply device of the apparatus for forming insulating film supplies a silane-based gas and oxygen gas for forming a silicon oxide insulating film as the gases for forming an insulating film into the second plasma producing chamber.
